(19) United States
(12) Patent Application Publication
(10) Pub. No.: US 2025/0324885 A1
(43) Pub. Date: Oct. 16, 2025

(54) DISPLAY APPARATUS AND ELECTRONIC DEVICE

(71) Applicant: Samsung Display Co., Ltd., Yongin-Si (KR)

(72) Inventors: Youngmin Cho, Yongin-si (KR); Woosuk Jang, Yongin-si (KR)

(21) Appl. No.: 19/030,717

(22) Filed: Jan. 17, 2025

(30) Foreign Application Priority Data
Apr. 11, 2024 (KR) 10-2024-0048853

(51) Int. Cl. H10K 59/80; H10K 102/00

(52) U.S. Cl. CPC H10K 59/872; H10K 59/873; H10K 2102/311

(57) ABSTRACT

A display apparatus and an electronic device include a display panel including a first area that is foldable and flat and a second area that extends from the first area and is curved, an optical functional layer on the first area and at least a portion of the second area and having at least a portion which is curved, a first cover member on the optical functional layer and overlapping the first area, a second cover member on the first cover member, overlapping the first area and the second area, and having at least a portion which is curved, and a housing in which the display panel, the optical functional layer, the first cover member, and the second cover member are accommodated.

### CROSS-REFERENCE TO RELATED APPLICATION

This application is based on and claims priority under 35 U.S.C. § 119 to Korean Patent Application No. 10-2024-0048853, filed on Apr. 11, 2024, in the Korean Intellectual Property Office, the disclosure of which is incorporated by reference herein in its entirety.

### BACKGROUND

### Field

One or more embodiments relate to an apparatus, and more particularly, to a display apparatus and an electronic device.

### Description of the Related Art

Display panels have become widely used in small electronic devices such as mobile phones, tablet personal computers (PCs), and other mobile electronic devices. A mobile electronic device may include a display panel that provides a user with visual information such as an image or a video, which may be provided in support various functions or user interfaces. With the miniaturization of various components for driving a display panel, the ability of the display panel in an electronic device to provide complex interfaces has become increasingly important, and for use in more miniaturized devices, flat display panels have been developed that may be bent.

### SUMMARY

Folding of a foldable display panel that is in a housing of a display apparatus may cause a position of an end of the display panel in the housing to change. The relative movement can cause problems. In particular, an edge portion of the display panel may need to be protected from external shock to avoid being fractured, and relative movement of the end of the display panel can make protection more difficult. Also, when the display panel is folded, interference may occur between an edge of the display panel and the housing. In accordance with an aspect of the present disclosure, a display apparatus and an electronic device can reduce interference between a display panel and a housing while protecting the display panel from fractures.

Additional aspects will be set forth in part in the description which follows and, in part, will be apparent from the description, or may be learned by practice of the embodiments presented below.

According to one or more embodiments, a display apparatus includes a display panel including a first area that is foldable and flat and a second area that extends from the first area and is curved, an optical functional layer disposed on the first area and at least a portion of the second area and having at least a portion which is curved, a first cover member disposed on the optical functional layer to correspond to the first area, a second cover member disposed on the first cover member, disposed to correspond to the first area and the second area, and having at least a portion which is curved, and a housing in which the display panel, the optical functional layer, the first cover member, and the second cover member are accommodated.

The display apparatus may further include a protective film disposed on a lower surface of the display panel.

The protective film may include an opening area corresponding to a boundary between the first area and the second area.

The second area may not overlap a folding axis with respect to which the display panel may fold.

The display apparatus may further include an elastic member disposed between the housing and the display panel.

The elastic member may include a porous member or a member including an inner cavity.

The housing may include a mounting groove in which the elastic member is mounted.

The first cover member may be disposed only on the first area.

The display apparatus may further include a cover member adhesive layer between the first cover member and the second cover member and a first adhesive member between the first cover member and the optical functional layer.

At least a portion of the cover member adhesive layer and at least a portion of the first adhesive member may be in contact with each other on the second area.

At least a portion of the cover member adhesive layer and at least a portion of the first adhesive member may be apart from each other on the second area.

The display apparatus may further include a brush portion disposed between the housing and the second cover member.

A surface of the housing facing the second cover member may be inclined or curved.

A side surface of the housing may include an avoidance groove.

According to one or more embodiments, a display apparatus includes a display panel having a foldable portion, a housing accommodating the display panel, and an elastic member disposed between the housing and the display panel and having a porous shape or including at least one cavity.

The display panel may include a first area that is flat and a second area that extends from the first area and is curved.

The elastic member may be disposed to correspond to the second area.

The display apparatus may further include a protective film including an opening area corresponding to the first area and the second area and disposed below the display panel.

The opening area may not overlap a folding axis with respect to which the display panel is folded.

The opening area may include a hole or a groove.

The display apparatus may further include an optical functional layer disposed on the display panel and a cover member disposed on the optical functional layer.

An end of an adhesive member disposed on the cover member and an end of an adhesive member disposed on the optical functional layer may be in contact with each other, and at least a portion of the adhesive member disposed on the cover member and at least a portion of the adhesive member disposed on the optical functional layer may be apart from each other.

The display apparatus may further include a brush portion disposed between the cover member and the housing.

The housing may include a mounting groove in which the elastic member is mounted.

The housing may include an avoidance groove accommodating a shifted end of the display panel when the display panel is folded.

According to one or more embodiments, an electronic device includes a display panel comprising a first area that is foldable and flat and a second area that extends from the first area and is curved, an optical functional layer on the first area and at least a portion of the second area, the optical functional layer having at least a portion which is curved, a first cover member on the optical functional layer and overlapping the first area, a second cover member on the first cover member, overlapping the first area and the second area, and having at least a portion which is curved, and a housing in which the display panel, the optical functional layer, the first cover member, and the second cover member are accommodated.

The electronic device may further include a protective film on a lower surface of the display panel and comprising an opening area that overlaps a boundary between the first area and the second area.

The electronic device may further include an elastic member between the housing and the display panel.

The electronic device may further include a cover member adhesive layer between the first cover member and the second cover member, and a first adhesive member between the first cover member and the optical functional layer, at least a portion of the first adhesive member being in contact with the cover member adhesive layer in the first area.

### BRIEF DESCRIPTION OF THE DRAWINGS

The above and other aspects, features, and advantages of certain embodiments of the disclosure will be more apparent from the following description taken in conjunction with the accompanying drawings.

FIG. 1A is a schematic perspective view of a display apparatus according to an embodiment.

FIG. 1B is a schematic perspective view of a folded state of the display apparatus illustrated in FIG. 1A.

FIG. 1C is a schematic cross-sectional view of the display apparatus of FIG. 1A taken along line A-A′ of FIG. 1A.

FIG. 1D is a schematic cross-sectional view of a portion of the display apparatus of FIG. 1A taken along line B-B′ of FIG. 1A.

FIGS. 2A, 2B, 2C, 2D, and 2E are schematic rear views of embodiments of a protective film illustrated in FIG. 1C.

FIG. 3 is a schematic plan view of arrangement of an elastic member and a reinforcement layer illustrated in FIGS. 1C and 1D.

FIGS. 4A and 4B are schematic cross-sectional views of embodiments of a first portion of the display apparatus illustrated in FIG. 1A, when the display apparatus is folded.

FIG. 5A is a schematic perspective view of a display apparatus according to another embodiment.

FIG. 5B is a schematic cross-sectional view of a portion of the display apparatus of FIG. 5A taken along line C-C′ of FIG. 5A.

FIGS. 6A, 6B, 6C, and 6D are schematic rear views of embodiments of a protective film illustrated in FIG. 5B.

FIG. 7 is a schematic plan view of arrangement of an elastic member and a reinforcement layer illustrated in FIG. 5B.

FIGS. 8A, 8B, 8C, 8D, and 8E are cross-sectional views of embodiments of an elastic member of a display apparatus.

FIG. 9 is a schematic plan view of a display panel illustrated in FIG. 1B or 5B.

FIG. 10 is a schematic circuit diagram of a pixel or sub-pixel in the display panel illustrated in FIG. 9.

FIG. 11 is a schematic cross-sectional view of a portion of an embodiment of the display panel of FIG. 9 taken along line D-D′ of FIG. 9.

FIG. 12 is a block diagram of an electronic device according to an embodiment.

FIGS. 13, 14, and 15 are schematic views of electronic devices according to various embodiments.

### DETAILED DESCRIPTION

The following describes in detail example embodiments, which are illustrated in the accompanying drawings. Like reference numerals refer to like elements throughout drawings and this specification. The example embodiments may be altered or have different forms, and this disclosure should not be construed as being limited to the example embodiments. Accordingly, the embodiments are merely described below, by referring to the figures, to explain aspects of the present disclosure.

While the disclosure is capable of various modifications and alternative forms, embodiments thereof are shown by way of example in the drawings and will herein be described in detail. Effects and characteristics of the disclosure and methods of achieving the same will become apparent by referring to the embodiments described in detail below along with the drawings. However, the disclosure is not limited to the embodiments disclosed hereinafter and may be realized in various forms.

As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

In the embodiments described hereinafter, the terms “first,” “second,” etc. are used to distinguish one element from another and are not used as a restrictive sense.

As used herein, the singular expressions “a,” “an,” and “the” are intended to include the plural forms as well, unless the context clearly indicates otherwise.

The terms “comprises” and/or “comprising” are used herein to specify the presence of stated features or elements but do not preclude the presence or addition of one or more other features or elements.

A layer, area, or element referred to as “on” another layer, area, or element may be directly or indirectly on the other layer, area, or element. That is, for example, intervening layers, areas, or elements may be present.

Sizes of elements in the drawings may be altered or exaggerated for convenience of explanation. For example, the elements in the drawings have sizes or thickness chosen for convenience of explanation, and thus, the disclosure is not necessarily limited to the dimensions shown in the drawings.

In the embodiments hereinafter, the x-axis, the y-axis and the z-axis are not limited to three perpendicular axes of the rectangular coordinate system and may be interpreted in a broader sense. For example, the x-axis, the y-axis, and the z-axis may be perpendicular to one another or may represent different directions that are not perpendicular to one another.

A specific process order described herein may be performed differently from the described order. For example, two processes described to have a process order may be performed substantially at the same time or performed in an order opposite to the described order.

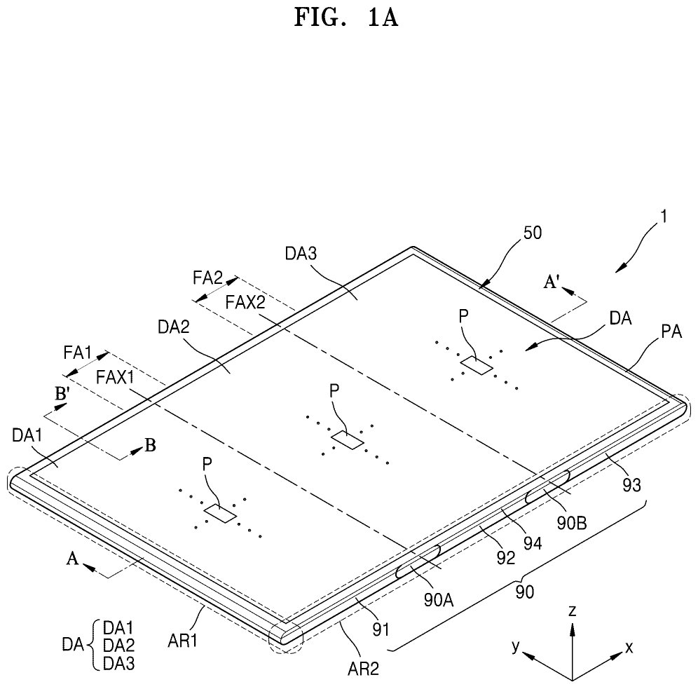

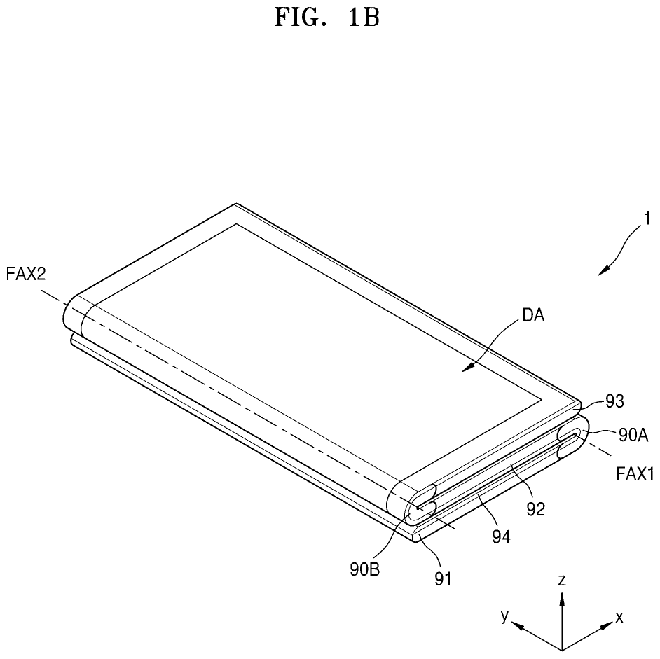

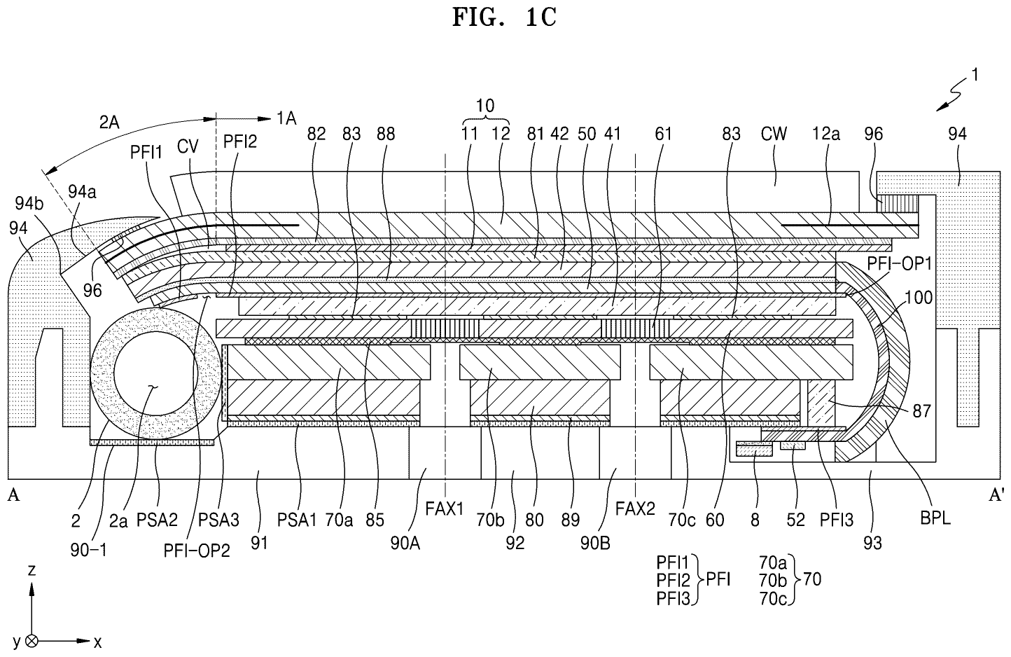

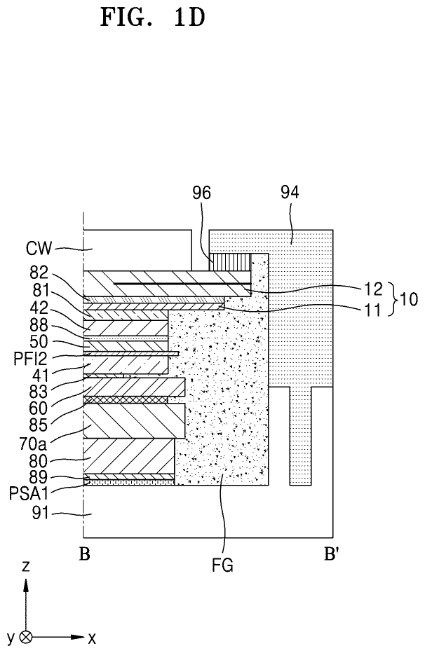

FIG. 1A is a schematic perspective view of an embodiment of a display apparatus 1 in an unfolded state. FIG. 1B is a schematic perspective view of the display apparatus 1 illustrated in FIG. 1A in a folded state.

Referring to FIGS. 1A and 1B, the display apparatus 1 may display a moving image or a static image and may be used as a display screen of an electronic device. For example, the display apparatus 1 may provide a display screen of a portable electronic device such as a mobile phone, a smartphone, a tablet personal computer (PC), a mobile communication terminal, an electronic notebook, an electronic book, a portable multimedia player (PMP), a navigation device, or an ultra-mobile PC (UMPC). Alternatively, the display apparatus 1 may provide a display screen in various products, such as a television (TV), a notebook computer, a monitor, a signboard, the Internet of things (IoT), etc. Also, the display apparatus 1 may be used in wearable devices, such as a smart watch, a watch phone, a glasses-type display, or a head-mounted display (HMD). Also, the display apparatus 1 may be used as: a center information display (CID) on a gauge of a vehicle or a center fascia or a dashboard of the vehicle; a room mirror display substituting a side-view mirror of a vehicle; or a display disposed on a rear surface of a front seat, as an entertainment device for a backseat of a vehicle.

The display apparatus 1 may include a display panel 50 and a housing 90. The display panel 50 may include a display area DA displaying an image and a peripheral area PA around the display area DA. Sub-pixels P including display elements may be in the display area DA. Here, the display area DA may contain multiple sub-pixels P that may be separated from each other. Some of the sub-pixels P may emit light of a first color, e.g., red, others of the sub-pixels P may emit light of a second color, e.g., green, and yet others of the sub-pixels P may emit light of a third color, e.g., blue. The display apparatus 1 may provide an image by using the light emitted from the sub-pixels P in the display area DA. The peripheral area PA may be a non-display area does not contain any of the sub-pixels P.

The display area DA may include a first display area DA1, a second display area DA2, and a third display area DA3. Each of the first display area DA1, the second display area DA2, and the third display area DA3 may include some of the sub-pixels P. The display apparatus 1 may provide an image through the sub-pixels P in the first display area DA1, the second display area DA2, and the third display area DA3. The peripheral area PA may surround the first display area DA1, the second display area DA2, and the third display area DA3.

The display panel 50 may display (output) information processed by the display apparatus 1. For example, the display apparatus 1 may run or execute and application, and the display panel 50 may display execution screen information such as a user interface (UI) or graphics UI (GUI) information according to the execution screen information from the application. The display panel 50 may include a display layer displaying an image and a touch screen layer sensing touch input of a user. Thus, the display panel 50 may function as an input device providing an input interface between the display apparatus 1 and a user, and at the same time, the display panel 50 may function as an output interface between the display apparatus 1 and the user.

Hereinafter, an organic light-emitting display apparatus is described as an example embodiment of the display apparatus 1. However, the display apparatus according to the disclosure is not limited thereto. Depending on the embodiment, the display apparatus 1 may include an inorganic light-emitting display apparatus, an inorganic electroluminescent (EL) display apparatus, or a quantum dot light-emitting display apparatus. For example, an emission layer of a display element included in the display apparatus 1 may include an organic material, an inorganic material, quantum dots, an organic material and quantum dots, or an inorganic material and quantum dots.

According to an embodiment, the display panel 50 may be a flexible display panel that is flexible and easily curved, folded, or rolled without being damaged. For example, the display panel 50 may include a foldable display panel which may be folded or unfolded, a curved display panel having a curved display surface, a bent display panel including bent portions excluding a display surface, a rollable display panel which may be rolled or unrolled, or a stretchable display panel which may be stretched. According to an embodiment, the display panel 50 may include a rigid display panel which is rigid and is not easily curved.

According to an embodiment, the display panel 50 may have a first folding axis FAX1 and a second folding axis FAX2. The display panel 50 may be folded about the first folding axis FAX1 or the second folding axis FAX2 without being damaged.

The first folding axis FAX1 may be between the first display area DA1 and the second display area DA2. Also, the second folding axis FAX2 may be between the second display area DA2 and the third display area DA3. That is, the first folding axis FAX1 and the second folding axis FAX2 may define boundaries of the first display area DA1, the second display area DA2, and the third display area DA3.

The housing 90 may form the exterior shape of a lower surface of the display apparatus 1. The housing 90 may be made of plastic, metal, or both plastic and metal. The housing 90 may include a first portion 91, a second portion 92, and a third portion 93 that support the display panel 50. The first portion 91 of the housing 90 may be folded about the first folding axis FAX1 relative to the second portion 92. Also, the third portion 93 of the housing 90 may be folded about the second folding axis FAX2 relative to the second portion 92.

According to an embodiment, a first hinge portion 90A may be between the first portion 91 and the second portion 92, and a second hinge portion 90B may be between the second portion 92 and the third portion 93.

According to an embodiment, the first display area DA1 and the second display area DA2 may be folded about the first folding axis FAX1 so that the first display area DA1 and the second display area DA2 face each other. That is, the first portion 91 and the second portion 92 may be folded about the first folding axis FAX1 so that the first portion 91 and the second portion face each other. According to an embodiment, the first display area DA1 and the second display area DA2 may be folded about the first folding axis FAX1 so as not to face each other, e.g., to face away from each other.

According to an embodiment, the second display area DA2 and the third display area DA3 may be folded about the second folding axis FAX1 so as to not to face each other, e.g., to face away from each other. That is, the second portion 92 and the third portion 93 may be folded about the second folding axis FAX2 to face each other. According to an embodiment, the second display area DA2 and the third display area DA3 may be folded about the second folding axis FAX2 to face each other.

According to an embodiment, in the case of in-folding in which the first display area DA1 and the second display area DA2 are folded to face each other, a curvature of a folded portion may be equal to or less than 5R (ex, R=1 mm). Alternatively, in the case of in-folding in which the first display area DA1 and the second display area DA2 are folded to face each other, the curvature of the folded portion may be equal to or less than 3R or equal to or less than 1R.

According to an embodiment, in the case of out-folding in which the second display area DA2 and the third display area DA3 are folded not to face each other, a curvature of a folded portion may be equal to or less than 5R. Alternatively, in the case of out-folding in which the second display area DA2 and the third display area DA3 are folded not to face each other, the curvature of the folded portion may be equal to or less than 4R.

FIG. 1C is a schematic cross-sectional view of the display apparatus 1 taken along line A-A′ of FIG. 1A. FIG. 1D is a schematic cross-sectional view of a portion of the display apparatus 1 taken along line B-B′ of FIG. 1A.

Referring to FIG. 1C, a cover member 10 may be above the display panel 50. According to an embodiment, the cover member 10 may cover an upper portion of the display panel 50. Accordingly, the cover member 10 may protect an upper surface of the display panel 50.

Although not shown, according to an embodiment, the cover member 10 may include a transmissive cover portion overlying the display panel 50 and a light-blocking cover portion overlying portions of the display apparatus 1, except for the display panel 50. The light-blocking cover portion may include a non-transparent light-blocking material. The light-blocking cover portion may include a pattern which may be shown to a user when an image is not displayed.

According to an embodiment, the cover member 10 may include a first cover member 11 and a second cover member 12. According to an embodiment, the first cover member 11 may include a transparent material. Here, the first cover member 11 may include glass, transparent synthetic resins, or the like. The first cover member 11 may include one or more layers.

According to an embodiment, the second cover member 12 may be disposed on an upper surface of the first cover member 11 and may prevent or minimize scratching, abrasions, etc. from damaging the first cover member 11. The second cover member 12 may include a non-transparent layer 12a in or on a portion of the second cover member 12, depending on the embodiment. According to an embodiment, the non-transparent layer 12a may be disposed at an edge of the second cover member 12. The non-transparent layer 12a may block light.

The second cover member 12 may include a first area 1A which is flat and a second area 2A extending from the first area 1A and having curvature. Here, the entirety of the second area 2A may be curved. The second area 2A may be at a first edge AR1 of FIG. 1A. Here, the first edge AR1 may face a bent portion of a substrate 100 of the display panel 50. However, the second cover member 12 at a second edge AR2, an edge which faces the second edge AR2, and an edge which faces the first edge AR1 of FIG. 1A, may be flat, as illustrated in FIG. 1C and FIG. 1D. Accordingly, a region of second cover member 12 at the first edge AR1 of the second cover member 12 may have curvature in an X-Z plane, and a region second cover member 12 at the second edge AR2, the edge which faces the second edge AR2, and the edge which faces the first edge AR1 may be flat in a Y-Z plane. Here, the region of the second edge AR2 may include places where the display panel 50 may be folded. That is, the first folding axis FAX1 and the second folding axis FAX2 may intersect the region of the second edge AR2. In this case, the first cover member 11 may be disposed only in the first area 1A. That is, the first cover member 11 may be entirely flat when the display apparatus is unfolded.

A cover member adhesive layer 82 may be between the first cover member 11 and the second cover member 12. Here, the cover member adhesive layer 82 may be on the entire lower surface of the second cover member 12.

The display panel 50 may be below the cover member 10. A display driver 52 may be directly on the substrate 100 of the display panel 50. In this case, the display panel 50 and a display circuit board (not shown) may be connected to each other through a flexible printed circuit board 8, etc. or the display panel 50 and the display circuit board may be directly connected to each other. At least a portion of the substrate 100 of the display panel 50 as described above may be bent. Here, a bending protective layer BPL may be on a bent portion of the substrate 100 to prevent the formation of cracks, etc. in the bent portion of the substrate 100. The bending protective layer BPL may include polymer resins, such as polyethylene terephthalate (PET), polyimide (PI), etc.

The bending protective layer BPL may be disposed to shield the bent portion of the display panel 50. Here, one end of the bending protective layer BPL may be in contact with an end of an optical functional layer 42 as shown in a cross-sectional view of FIG. 1C.

According to an embodiment, the optical functional layer 42 may be disposed above the display panel 50, and a panel protective member 41 may be disposed below the display panel 50. Here, the optical functional layer 42 may be disposed between the first cover member 11 and the display panel 50. Also, a touch screen layer (not shown) configured to receive a touch signal from a user may be provided above the display panel 50.

According to an embodiment, the optical functional layer 42 may be disposed on the touch screen layer. The optical functional layer 42 may include a reflection prevention layer. The reflection prevention layer may reduce reflectivity of light (external light) incident through the display apparatus 1 from the outside.

According to some embodiments, the reflection prevention layer may include a polarization film. The polarization film may include a linear polarization plate and a phase delay film such as a quarter-wave (λ/4) plate. The phase delay film may be on the touch screen layer, and the linear polarization plate may be on the phase delay film.

According to an embodiment, the reflection prevention layer may include a filter layer including a black matrix and color filters. The color filters may be arranged according to the color of light emitted from each of the sub-pixels in the display apparatus 1. For example, the filter layer may include a red, green, or blue color filter above a sub-pixel that emits red, green, or blue light.

According to an embodiment, the reflection prevention layer may include a destructive interference structure. The destructive interference structure may include a first reflective layer and a second reflective layer disposed on different layers from each other. First reflective light and second reflective light reflected from the first reflective layer and the second reflective layer, respectively, may destructively interfere, and thus, the reflectivity of external light may be decreased.

The optical functional layer 42 as described above may determine a position of an end of the bending protective layer BPL. That is, when forming the bending protective layer BPL, the bending protective layer BPL may be formed using resins that may be applied to the substrate 100 of the display panel 50 after the optical function layer 42 is formed on the display panel 50. Here, the bending protective layer BPL may be movable, and thus, may not remain at a constant location on the display panel 50, and the bending protective layer BPL may shift on the display panel 50 in various directions. However, when the optical functional layer 42 is disposed on the display panel 50, an end of the optical functional layer 42 may not only prevent the introduction of the bending protective layer BPL to an area of the display panel 50, on which the optical functional layer 42 is disposed, but may also limit an area to which the bending protective layer BPL may shift. Thus, the bending protective layer BPL may be limited to the peripheral area PA of the display panel 50 and may not extend into the display area DA.

A fifth adhesive member 88 may be disposed between the optical functional layer 42 and the display panel 50. The fifth adhesive member 88 may attach the optical functional layer 42 onto the display panel 50. Here, the fifth adhesive member 88 may include a pressure sensitive adhesive (PSA) or a transparent adhesive member, such as an optically clear adhesive (OCA) film.

The optical functional layer 42, the fifth adhesive member 88, and the display panel 50 may have some flat portions and other curved portions, similarly to a surface shape of the second cover member 12.

The cover member 10 may be above the optical functional layer 42. The cover member 10 may be attached onto the optical functional layer 42 through a first adhesive member 81. According to an embodiment, the first adhesive member 81 may include a PSA or a transparent adhesive member such as an OCA film.

An end of the first adhesive member 81 and an end of the cover member adhesive layer 82 may be attached to each other. Here, a portion of the first adhesive member 81 and a portion the cover member adhesive layer 82, the portions being adjacent to the end of the first adhesive member 81 and the end of the cover member adhesive layer 82, respectively, may be separated from each other. The first cover member 11 may be between the first adhesive member 81 and the cover member adhesive layer 82. Here, an upper surface of the first adhesive member 81, a lower surface of the cover member adhesive layer 82, and a side surface of the first cover member 11 may form a space CV. The space CV may function as a buffer partially alleviating a force, which may be applied to the cover member 10 or a cover window CW.

According to an embodiment, a protective film PFI may be below the display panel 50. In this case, the protective film PFI may absorb shocks applied from outside the display apparatus 1. In this case, the protective film PFI may include a first opening area PFI_OP1 corresponding to a bending area of the display panel 50, which is to be described below. Here, a width of the first opening area PFI_OP1 may be less than a width of the bending area of the display panel 50.

The panel protective member 41 may be below the protective film PFI. The panel protective member 41 may be attached below the protective film PFI through a PSA. However, the disclosure is not limited thereto.

The protective film PFI may include a first protective film PFI1 and a second protective film PFI2, which may be connected to each other. Also, the protective film PFI may include a third protective film PFI3, which may be separated from the second protective film PFI2 with the separation defining the first opening area PFI-OP1. At least one of the first protective film PFI1 and the second protective film PFI2 may include a second opening area PFI-OP2. Here, the second opening area PFI-OP2 may be between the first protective film PFI1 and the second protective film PFI2. Also, the second opening area PFI-OP2 may overlap a boundary between the first area 1A and the second area 2A.

In this case, portions of the protective film PFI may have a flat shape, and other portions of the protective film PFI may have a curved shape, similarly to the surface shape of the second cover member 12. For example, the first protective film PFI1 may be flat, and the second protective film PFI2 may be curved.

According to an embodiment, a digitizer 70 may be disposed below the display panel 50. Here, the digitizer 70 may include a pattern layer to sense a signal input from an external electronic pen, etc. In particular, the digitizer 70 may sense the intensity, a direction, etc. of the signal input from the electronic pen, etc. The digitizer 70 may be electrically connected to a main circuit board separately provided. However, the disclosure is not limited thereto.

The digitizer 70 according to an embodiment may include a first portion 70a, a second portion 70b, and a third portion 70c. According to an embodiment, the first portion 70a of the digitizer 70 may at least partially overlap the first display area DA1, and the second portion 70b of the digitizer 70 may at least partially overlap the second display area DA2. The third portion 70c of the digitizer 70 may at least partially overlap the third display area DA3. Also, the first portion 70a and the second portion 70b of the digitizer 70 may at least partially overlap a first folding area FA1, and the second portion 70b and the third portion 70c of the digitizer 70 may at least partially overlap a second folding area FA2.

According to an embodiment, the first portion 70a and the second portion 70b of the digitizer 70 may be apart from each other in a first direction (an x direction) with the first folding axis FAX1 therebetween. Also, the second portion 70b and the third portion 70c of the digitizer 70 may be apart from each other in the first direction (the x direction) with the second folding axis FAX2 therebetween. That is, the digitizer 70 may be provided as a separate type, rather than an integral type. Because the digitizer 70 may be provided to have a separated structure, the occurrence of cracks, etc. in the digitizer 70 in the first folding area FA1 and the second folding area FA2 may be prevented or minimized.

In this case, the digitizer 70 having the separated structure may at least partially overlap the first folding area FA1 and the second folding area FA2, and thus, signals may be received also in the first folding area FA1 and the second folding area FA2. Thus, user convenience may be improved.

According to an embodiment, a plate 60 may be disposed between the display panel 50 and the digitizer 70. According to an embodiment, the plate 60 may be disposed below the display panel 50 to support the display panel 50.

The plate 60 may have various structures according to whether or not the display apparatus 1 is foldable and according to a folding type. For example, when the display apparatus 1 is not foldable, the plate 60 may have a fixed shape.

According to an embodiment, the plate 60 may include a folding structure 61. The shape or the length of the folding structure 61 may change when the display apparatus 1 is folded. According to an embodiment, the folding structure 61 may include a pattern portion including an opening, a concavo-convex portion, links connected to each other to be rotatable, or the like. However, the disclosure is not limited thereto.

According to an embodiment, when the display apparatus 1 is folded, the folding structure 61 may be folded about (or based on) the first folding axis FAX1 and the second folding axis FAX2. According to an embodiment, both sides of each folding structure 61 may be symmetrical with respect to (or based on) the first folding axis FAX1 or the second folding axis FAX2. According to an embodiment, the plate 60 excluding the folding structure 61 may have a flat upper surface.

According to an embodiment, the plate 60 may include at least one of glass, plastic, and metal. According to an embodiment, the plate 60 may include glass and plastic, glass and metal, plastic and metal, or glass, plastic, and metal. According to an embodiment, the folding structure 61 may include at least one of glass, plastic, and metal.

According to an embodiment, the folding structure 61 of the plate 60 may include a metal material, and remaining portions of the plate 60 except for the folding structure 61 may include a non-metal material. However, the disclosure is not limited thereto.

Referring to FIG. 1C again, according to an embodiment, a second adhesive member 83 may attach the plate 60 to the panel protective member 41. According to an embodiment, the second adhesive member 83 may include a PSA or a transparent adhesive member such as an OCA film.

According to an embodiment, a third adhesive member 85 may attach the plate 60 to the digitizer 70. According to an embodiment, the third adhesive member 85 may include a PSA, an OCA film, or thermoplastic polyurethane (TPU).

According to an embodiment, the third adhesive member 85 may be placed below the plate 60 and may prevent or minimize the introduction of impurities into the folding structure 61 of the plate 60.

According to an embodiment, a cushion layer 80 may be disposed below the digitizer 70. According to an embodiment, the cushion layer 80 may prevent or minimize damage that shocks from outside the display apparatus 1 might otherwise cause to the digitizer 70 disposed on the cushion layer 80.

According to an embodiment, an insulating film 89 may be below the cushion layer 80. Here, a sixth adhesive member PSA1 may attach the insulating film 89 to the housing 90.

According to an embodiment, a fourth adhesive member 87 may be below the digitizer 70. According to an embodiment, the fourth adhesive member 87 may include a PSA or an OCA film. However, the disclosure is not limited thereto. Although not shown, according to an embodiment, the digitizer 70 may be connected through the fourth adhesive member 87 to a main circuit board separately provided. However, the disclosure is not limited thereto.

The main circuit board (not shown in FIG. 1C) may be connected to the display panel 50 through the flexible printed circuit board 8, etc.

The main circuit board may include a main processor (not shown), a camera device (not shown), a main connector (not shown), and components (not shown). The main processor may be an integrated circuit. The camera device may be on both an upper surface and a lower surface of the main circuit board, and each of the main processor and the main connector may be on either of the upper surface and the lower surface of the main circuit board.

The main processor may control all functions of the display apparatus 1. For example, the main processor may output digital video data to the display driver 52 so that the display panel 50 may display an image. Also, the main processor may receive sensing data from a touch sensor driver (not shown). The main processor may determine whether or not there is a user's touch according to the sensing data and may perform an operation corresponding to a user's direct or proximate touch. For example, the main processor may calculate touch coordinates of the user by analyzing the sensing data and then may execute an application or perform an operation indicated by an icon touched by the user. The main processor may include an application processor, a central processing unit, or a system chip including an integrated circuit.

The camera device may process an image frame such as a static image or a motion image, obtained through an image sensor in a camera mode and may output the processed image frame to the main processor. The camera device may include at least one of a camera sensor (for example, a charge-coupled device (CCD) sensor, a complementary metal-oxide semiconductor (CMOS) sensor, etc.), a photo sensor (or the image sensor), and a laser sensor. The camera device may be connected to the image sensor from among the components arranged to overlap a component area and may process an image input to the image sensor.

A cable passing through a cable hole of a bracket may be connected to the main connector, and thus, the main circuit board may be electrically connected to the display circuit board.

In addition to the main processor, the camera device, and the main connector, the main circuit board may further include at least one wireless communicator, at least one input portion, at least one sensor portion, at least one output portion, at least one interface portion, a memory, and a power supply portion.

The wireless communicator may include at least one of a broadcasting reception module, a mobile communication module, a wireless Internet module, a short-range wireless communication module, and a position information module.

The broadcasting reception module may receive, from an external broadcasting management server, a broadcasting signal and/or broadcasting-related information, through a broadcasting channel. The broadcasting channel may include a satellite channel and a ground wave channel.

The mobile communication module may transmit and receive a wireless signal to and from at least one of a base station, an external terminal, and a server on mobile communication networks established according to the technical standards for mobile communication or the communication methods (for example, a global system for mobile communication (GSM), code division multiple access (CDMA), CDMA 2000, enhanced voice-data optimized or enhanced voice-data only (EV-DO), wideband CDMA (WCDMA), high speed downlink packet access (HSDPA), high speed uplink packet access (HSUPA), long term evolution (LTE), LTE-advanced (LTE-A), etc.). The wireless signal may include a sound call signal, a video telephony call signal, or various forms of data according to transmission and reception of text/multimedia messages.

The wireless Internet module may refer to a module for wireless Internet access. The wireless Internet module may be configured to transmit and receive a wireless signal on a communication network according to the wireless Internet techniques or protocols. The wireless Internet techniques may include, for example, a wireless local area network (WLAN), wireless-fidelity (Wi-fi), Wi-fi direct, a digital living network alliance (DLNA), etc.

The short-range wireless communication module may be used for short-range communication and may support short-range communication by using at least one of Bluetooth™, radio frequency identification (RFID), infrared data association (IrDA), an ultra wideband (UWB), Zigbee, near-field communication (NFC), Wi-fi, Wi-fi direct, and a wireless universal serial bus (USB). The short-range wireless communication module may support wireless communication between the display apparatus 1 and a wireless communication system, between the display apparatus 1 and another electronic device, or between the display apparatus 1 and a network on which another electronic device (or an external server) is located, through a short-range wireless communication network. The short-range wireless communication network may include a wireless personal area network. The other electronic device may include a wearable device which may exchange data (or which may be synchronized) with the display apparatus 1.

The position information module may include a module configured to obtain a position (or a current position) of the display apparatus 1, and representative examples of the position information module may include a global positioning system (GPS) module or a Wi-fi module. The display apparatus 1 may use the GPS module to use a signal transmitted from a GPS satellite to obtain the position of the display apparatus 1. Also, the display apparatus 1 may use the Wi-fi module to obtain the position of the display apparatus 1 based on information of a wireless access point (AP) transmitting or receiving a wireless signal to and from the Wi-fi module. The position information module may include modules used to obtain a position (or a current position) of the display apparatus 1 and is not limited to modules directly calculating or obtaining the position of the display apparatus 1.

The input portion may include an image input portion such as the camera device configured to input an image signal, a sound input portion such as a microphone configured to input a sound signal, and an input device configured to receive information from a user.

The camera device may process an image frame, such as a static image or a motion image, obtained through the image sensor in a video call mode or a photographing mode. The processed image frame may be displayed on the display panel 50 or stored in memory.

The microphone may process an external sound signal into electrical sound data. The processed sound data may be variously used according to a function performed (or an application executed) by the display apparatus 1. The microphone may use various noise removal algorithms for removing noise occurring in a process of receiving the external sound signal.

The main processor may control operations of the display apparatus 1 according to information input through an input device. The input device may include a mechanical input device, such as a button, a dome switch, a jog wheel, a jog switch, etc. on a rear surface or a side surface of the display apparatus 1 or a touch input device. The touch input device may be formed as the touch screen layer of the display panel 50.

The sensor portion may include one or more sensors configured to sense at least one of information in the display apparatus 1, information of an ambient environment surrounding the display apparatus 1, and user information and to generate a sensing signal according to the sensed information. Based on the sensing signal, the main processor may be configured to drive the display apparatus 1, control operations of the display apparatus 1, or process data and perform functions or operations related to an application installed on the display apparatus 1. The sensor portion may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environmental sensor (for example, a barometer, a hygrometer, a thermometer, a radioactivity sensor, a heat sensing sensor, a gas sensing sensor, etc.), and a chemical sensor (for example, an electronic nose, a healthcare sensor, a biometric sensor, etc.).

The proximity sensor refers to a sensor configured to detect the presence or absence of an object approaching a predetermined detection surface or a nearby object without mechanical contact by using the force of an electromagnetic field or infrared rays. Examples of the proximity sensor include a transmission-type photoelectric sensor, a direct reflection-type photoelectric sensor, a mirror reflection-type photoelectric sensor, a high frequency oscillation-type proximity sensor, a capacitive proximity sensor, a magnetic proximity sensor, an infrared proximity sensor, etc. The proximity sensor may sense not only a proximate touch, but also a proximate touch pattern, such as a proximate touch distance, a proximate touch direction, a proximate touch speed, a proximate touch time, a proximate touch position, and a proximate touch movement state. The main processor may be configured to process data (or information) corresponding to the proximate touch operation and the proximate touch pattern sensed by the proximity sensor, and the main process may control the display panel 50 to display visual information corresponding to the processed data.

The ultrasonic sensor may be configured to recognize location information of an object by using ultrasonic waves. The main processor may be configured to calculate a location of an object through the information sensed from the optical sensor and the plurality of ultrasonic sensors. According to a location of the object, the speed of light and the speed of ultrasonic waves may vary, and thus, the location of the object may be calculated by using the time in which the light reaches the optical sensor and the time in which the ultrasonic waves reach the ultrasonic sensor.

The output portion may be configured to generate an output related to a visual sense, an auditory sense, a haptic sense, or the like and may include at least one of the display panel 50, a sound output portion, a haptic module, and a light output portion.

The sound output portion may output sound data which is received from the wireless communicator in a call signal reception mode, a call mode, a recording mode, a voice recognition mode, a broadcasting reception mode, etc. or stored in the memory. The sound output portion may output a sound signal (for example, a call signal reception sound, a message reception sound, etc.) related to a function performed by the display apparatus 1. The sound output portion may include a receiver and a speaker. At least one of the receiver and the speaker may include a sound generation device which is attached below the display panel 50 and vibrates the display panel 50 to output sound. The sound generation device may include a piezoelectric element or a piezoelectric actuator contracting or expanding according to an electrical signal or an exciter vibrating the display panel 50 by generating a magnetic force by using a voice coil.

The haptic module may generate various haptic effects which may be felt by a user. The haptic module may provide vibration to the user as a haptic effect. The intensity, the pattern, or the like of the vibration generated in the haptic module may be controlled according to selection of the user or the setting of the main processor. For example, the haptic module may synthesize and output different vibrations or may sequentially output different vibrations. The haptic module may generate various haptic effects including not only vibration, but also stimulus-based effects, such as pin arrangement performing a vertical motion with respect to a skin surface in contact, an injective force or a suction force of air though an injection hole or a suction hole, brushing against a skin surface, contact with an electrode, and an electrostatic force, as well as effects based on representation of cold and warmth sensation using a device capable of heat absorption or heat radiation. The haptic module may transmit the haptic effects through direct contact. Also, the haptic module may be configured to allow a user to feel the haptic effects through sensation of muscles such as a finger, an arm, etc.

The light output portion may use light from a light source to output a signal for notifying an occurrence of an event. Examples of the event occurring in the display apparatus 1 may include message reception, call signal reception, an absent call, alarm, schedule notification, email reception, information reception through an application, etc. The signal output by the light output portion may be realized via emission of light of a single color or a plurality of colors on a front surface or a rear surface of the display apparatus 1. The outputting of the signal may be ended via sensing of the display apparatus 1 with respect to user's identification of an event.

The interface portion may serve as a path between the display apparatus 1 and various types of external devices connected to the display apparatus 1. The interface portion may include at least one of a wired/wireless headset port, an external charger port, a wired/wireless data port, a memory card port, a port connecting a device including an identification module, an audio input/output (I/O) port, a video I/O port, and an carphone port. The display apparatus 1 may perform an appropriate control operation related to an external device connected thereto, when the external device is connected to the interface portion.

The memory may store data supporting various functions of the display apparatus 1. The memory may store a plurality of applications to be driven or executed in the display apparatus 1 and data and instructions for operations of the display apparatus 1. At least some of the plurality of applications may be downloaded from an external server through wireless communication. The memory may store an application for an operation of the main processor and may temporarily store input/output data, for example, data such as a phone book, a message, a static image, a motion image, etc. Also, the memory may store haptic data for vibration of various patterns provided to the haptic module and sound data with respect to various sound provided to the sound output portion. The memory may include a storage medium of at least one type from among a flash memory type, a hard disk type, a solid state disk (SSD) type, a silicon disk driver (SDD) type, a multimedia card micro type, a card type memory (for example, a secure digital (SD) or extreme digital (XD) memory, etc.) random-access memory (RAM), static RAM (SRAM), read-only memory (ROM), electrically erasable programmable ROM (EEPROM), programmable ROM (PROM), a magnetic memory, a magnetic disk, and an optical disk.

The power supply portion may supply power to each component included in the display apparatus 1, by receiving external power and internal power under control by the main processor. The power supply portion may include a battery. Also, the power supply portion may include a connection port, and the connection port may be an example of the interface portion, to which an external charger supplying power for charging the battery is electrically connected. Alternatively, the power supply portion may be configured to charge the battery by using a wireless method, rather than the connection port. The battery may receive power from an external wireless power transmission device, by using one or more of an inductive coupling method based on magnetic induction and a magnetic resonance coupling method based on electro-magnetic resonance. The battery may be arranged not to overlap the main circuit board in a third direction (a Z direction). The battery may overlap a hole in the bracket.

The housing 90 may be arranged below the main circuit board and the battery. The housing 90 may form the exterior shape of a lower surface of the display apparatus 1. The housing 90 may include plastic, metal, or both plastic and metal. The housing 90 may include an upper housing 94 coupled to each of the first portion 91, the second portion 92, and the third portion 93. Here, the upper housing 94 may be separately connected to each of the first to third portions 91 to 93 and may include an additional hinge corresponding to each of a first hinge portion 90A, a second hinge portion 90B, and a third hinge portion 90C. The upper housing 94 may include an inclined surface 94a. Also, a surface of the upper housing 94 may include an avoidance groove 94b including a dented portion. The avoidance groove 94b may provide a space in which at least one of the protective film PFI, the display panel 50, the optical functional layer 42, the cover member 10, and the cover window CW may be shifted when the display apparatus 1 is folded.

The housing 90 may include a mounting groove 90-1 in which an elastic member 2 resides. The mounting groove 90-1 may be an indentation in a lower surface of the housing 90 and may be shaped to accommodate a portion of the elastic member 2. The mounting groove 90-1 may not only accommodate the elastic member 2 but may also provide an avoidance space when at least one of the cover member 10, the optical functional layer 42, the display panel 50, the panel protective member 41, and the protective film PFI is pressed against the lower surface of the housing 90.

A brush portion 96 may be disposed between the upper housing 94 and the cover member 10. The brush portion 96 may block the introduction of contamination into a space between the upper housing 94 and the cover member 10. Here, the brush portion 96 may include microfibers or protrusions and may contact an upper surface of the cover member 10.

The elastic member 2 may be below the first area 1A or the second area 2A. Here, the elastic member 2 may be accommodated in a space below the protective film PFI. In this case, when a force is applied from the side of the cover member 10 or the cover window CW, the clastic member 2 may absorb the shock applied to at least one of the protective film PFI, the display panel 50, the optical functional layer 42, the cover member 10, and the cover window CW. Also, when at least a portion of the display apparatus 1 shifts toward the housing 90 when the display apparatus 1 is folded, the clastic member 2 may support at least a portion of the shifted portion of the display apparatus 1. Here, the shape of the elastic member 2 may change in response to the shifted portion. The elastic member 2 may include rubber, urethane, etc. Also, the elastic member 2 may include at least one cavity 2a. Here, the elastic member 2 may be at or adjacent to the first edge AR1 of FIG. 1A. Also, the elastic member 2 may be elongated, having a length similar to at least one of the edges of the display apparatus 1. For example, the elastic member 2 may have a length that is about the same as the length of the edge AR1 of the display apparatus 1. The length of the elastic member 2 may extend parallel to the first folding axis FAX1 or the second folding axis FAX2.

The elastic member 2 may be fixed by an adhesive member. For example, the elastic member 2 may be fixed to the housing 90 through a seventh adhesive member PSA2 in the housing 90. Also, the elastic member 2 may be fixed to the housing 90 through an eighth adhesive member PSA3 at a side surface of at least one of the digitizer 70, the cushion layer 80, and the insulating film 89.

A reinforcement layer FG shown in FIG. 1D may be at or adjacent to the second edge AR2 of FIG. 1A. The reinforcement layer FG may contain resins and may be cured. Here, the housing 90 may accommodate the reinforcement layer FG. The upper housing 94 may or may not be at the second edge AR2, where the reinforcement layer FG resides. When the upper housing 94 is not at the second edge AR2, the reinforcement layer FG may surround at least a portion of an upper surface of the second cover member 12 and a side surface of the display apparatus 1. Here, the second edge AR2 may refer to at least one of the edges of the display apparatus 1, at the ends of the first edge AR1.

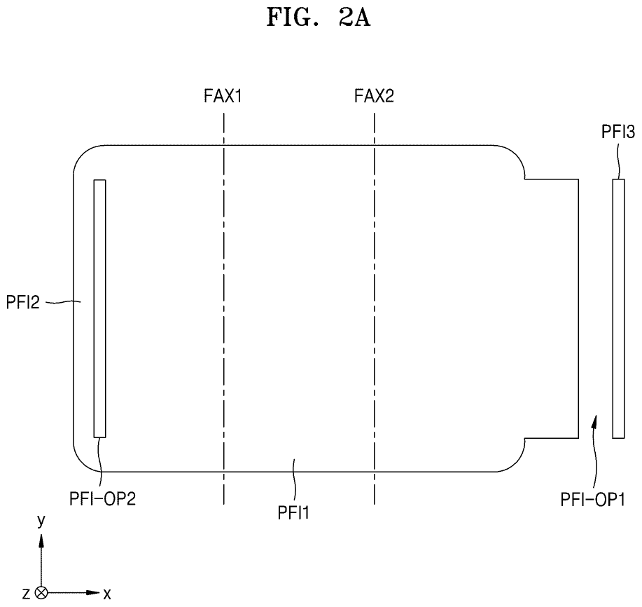

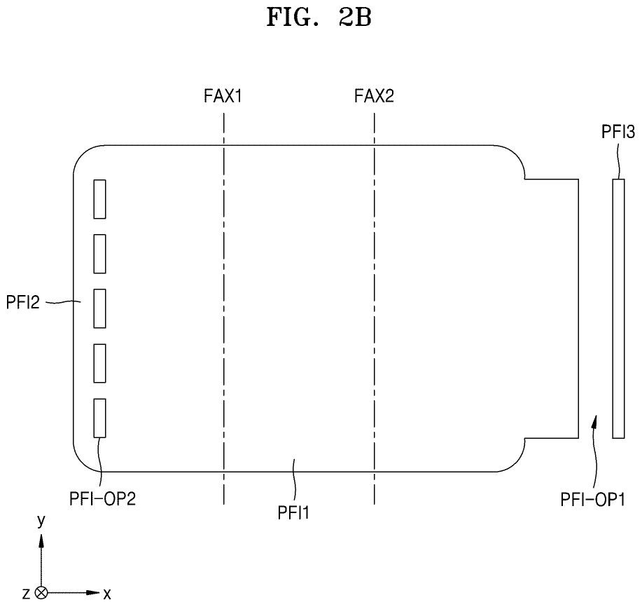

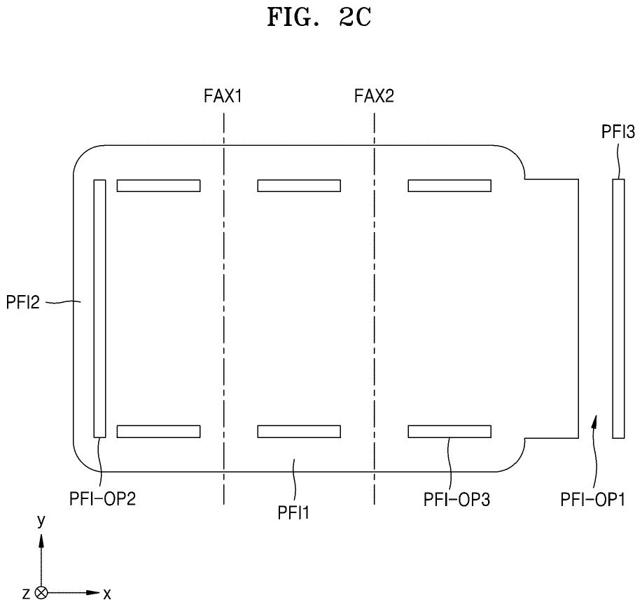

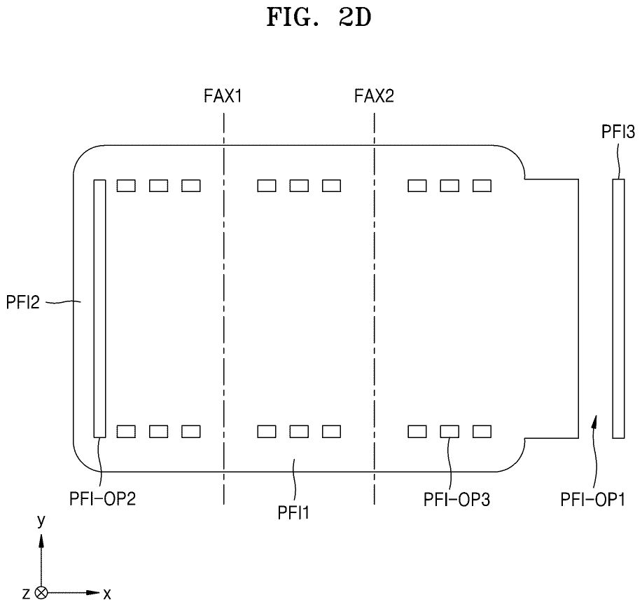

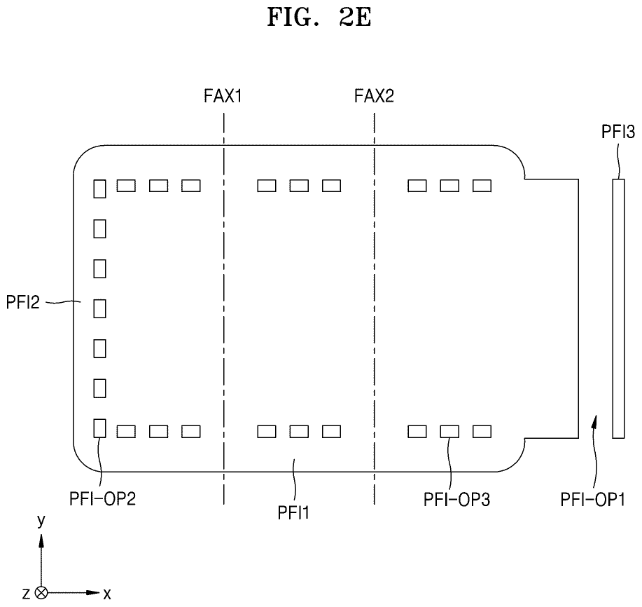

FIGS. 2A to 2E are schematic rear views of embodiments of the protective film PFI illustrated in FIG. 1C.

Referring to FIG. 2A, the protective film PFI may include the first protective film PFI1, the second protective film PFI2, and the third protective film PFI3. Here, the first protective film PFI1 and the second protective film PFI2 may be connected to each other. Also, the second opening area PFI-OP2 may be between the first protective film PFI1 and the second protective film PFI2. Here, the second opening area PFI-OP2 may extend as a straight line or strip. Also, the second opening area PFI-OP2 may be a hole from which the protective film PFI is completely removed. The third protective film PFI3 may be separated from the second protective film PFI2. Here, the first opening area PFI-OP1 may be between the third protective film PFI3 and the second protective film PFI2.

The first opening area PFI-OP1 may correspond to a bending area to be described further below. Also, the second opening area PFI-OP2 may overlap a boundary between the first area 1A and the second area 2A as described above.

Referring to FIG. 2B, the second opening area PFI-OP2 may include multiple second opening areas PFI-OP2 that are separated from each other. Here, the plurality of second opening areas PFI-OP2 may be arranged in series. The series of second opening areas PFI-OP2 may be arranged parallel with the first folding axis FAX or the second folding axis FAX2.

Referring to FIG. 2C, the protective film PFI may further include a third opening area PFI-OP3. Here, the third opening area PFI-OP3 may be arranged along a different direction from the length direction of the second opening area PFI-OP2. Also, the third opening area PFI-OP3 may not overlap the first folding axis FAX1 and the second folding axis FAX2. That is, each third opening area PFI-OP3 may be in an unfolded portion of the protective film PFI. The third opening area PFI-OP3 may extend along an edge of the protective film PFI with the first folding axis FAX1 or the second folding axis FAX2 between adjacent regions of the third opening area PFI-OP3. Here, one third opening area PFI-OP3 or a pair of third opening areas PFI-OP3 may be arranged in each of the areas bounded by the first folding axis FAX1 or the second folding axis FAX2. For example, in FIG. 2D, the first folding axis FAX1 and the second folding axis FAX2 may divide the protective film PFI into three areas, and a pair of third opening areas PFI-OP3 may be in each of these areas. Although not shown, an embodiment may have one third opening area PFI-OP3 in each area.

Referring to FIG. 2D, a plurality of third opening areas PFI-OP3 may be provided in each of a plurality of areas of the protective film PFI bounded by the first folding axis FAX1 or the second folding axis FAX2. Here, the plurality of third opening areas PFI-OP3 may be serially arranged in each area. Also, two series of the third opening areas PFI-OP3 may be in each area at opposite edges as illustrated in FIG. 2D, or although not shown in FIG. 2D, a series of third opening areas PFI-OP3 may be arranged at only one side of each area.

Referring to FIG. 2E, the second opening areas PFI-OP2 and the third opening areas PFI-OP3 may each include one or more series of openings. Here, the second opening areas PFI-OP2 may be arranged as described with reference to FIG. 2B, and the third opening areas PFI-OP3 may be arranged as described with reference to FIG. 2D.

As described above, at least one of the second opening area PFI-OP2 and the third opening area PFI-OP3 may permit deformation of an edge of the display apparatus 1 to some extent when external shocks are applied to the display apparatus 1. That is, if the second opening area PFI-OP2 or the third opening area PFI-OP3 is present, the protective film PFI may be in most portions of the display apparatus 1, and thus, when a shock is applied from an upper surface of the display apparatus 1, the protective film PFI may not deform to prevent deformation of at least one of the protective film PFI, the display panel 50, the optical functional layer 42, the cover member 10, and the cover window CW. However, by providing at least one of the second opening area PFI-OP2 and the third opening area PFI-OP3 in the protective film PFI, an edge portion of the display apparatus 1 may be less rigid than are other portions of the display apparatus 1 and may deform to better protect the other portions of the display apparatus 1.

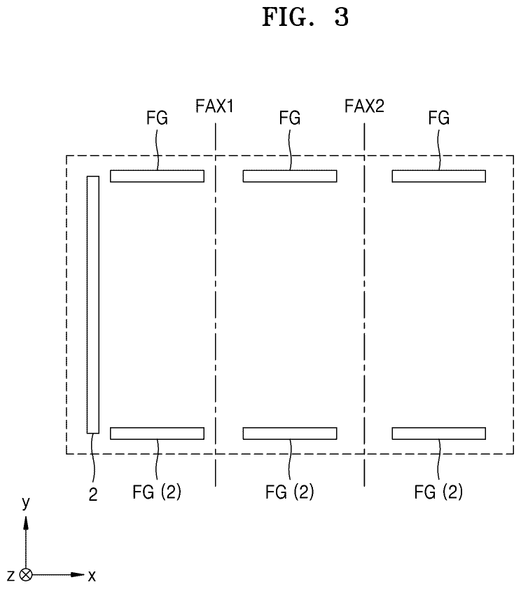

FIG. 3 is a schematic plan view of an embodiment of the elastic member 2 and the reinforcement layer FG illustrated in FIGS. 1C and 1D.

Referring to FIG. 3, the elastic member 2 and the reinforcement layer FG may be at different locations. For example, the elastic member 2 may be at a side of the display apparatus 1 that is parallel to but not overlapping the first folding axis FAX1 and the second folding axis FAX2. The reinforcement layer FG may be adjacent to sides of the display apparatus 1 that are perpendicular to the first folding axis FAX1 and the second folding axis FAX2. In this case, at least one region of the reinforcement layer FG may be provided, and each region of the reinforcement layer FG may not overlap the first folding axis FAX1 or the second folding axis FAX2. When the regions of the reinforcement layer FG are provided, one region of the reinforcement layer FG or a pair of regions of the reinforcement layers FG may be in each area of the display apparatus 1 bounded by the first folding axis FAX1 or the second folding axis FAX2.

Although not shown in FIG. 3, the elastic member 2 may replace the reinforcement layer FG. More specifically, the reinforcement layer FG may be absent, and copies of the clastic member 2 may be in locations corresponding to the regions of the reinforcement layer FG shown in FIG. 3. In this case, the elastic member 2 may be disposed between the cover member 10 and the housing 90, similarly to FIG. 1C.

Depending on the embodiment, multiples or copies of at least one of the elastic member 2 and the reinforcement layer FG may be provided such that the elastic members 2 or the reinforcement layers FG may be spaced apart from each other. In this case, the plurality of elastic members 2 may be serially arranged, similarly to the second opening areas PFI-OP2 illustrated in FIG. 2B or FIG. 2E, and the plurality of regions of the reinforcement layer FG may be serially arranged in each area of the display apparatus 1 bounded by the first folding axis FAX1 or the second folding axis FAX2, similarly to the third opening areas PFI-OP3 illustrated in FIG. 2D or 2E.

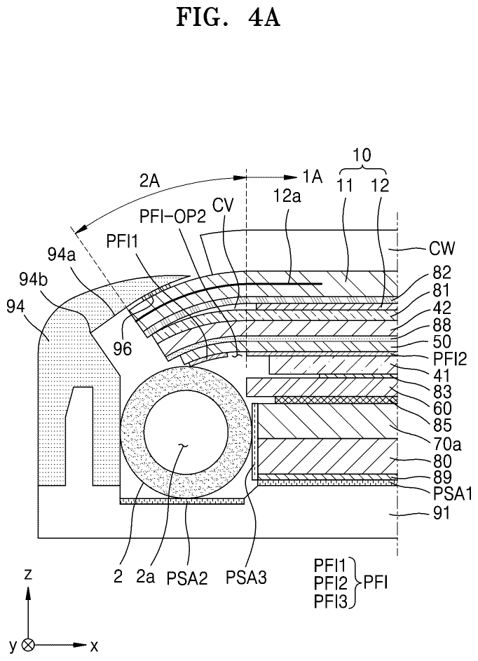

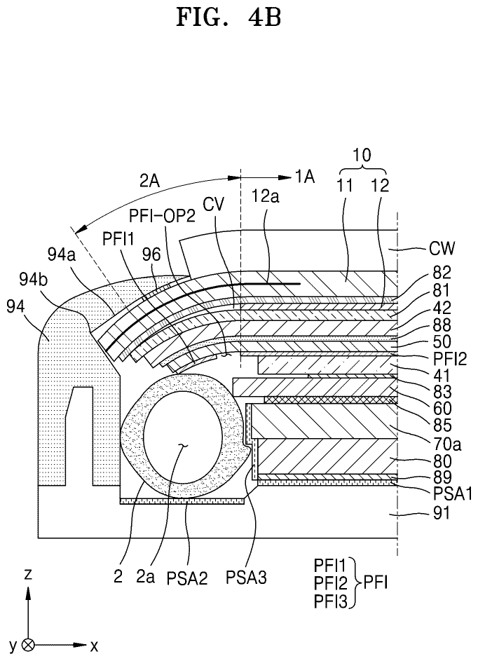

FIGS. 4A and 4B are schematic cross-sectional views of a first portion of the display apparatus 1 before and after the display apparatus 1 illustrated in FIG. 1A is folded.

Referring to FIGS. 4A and 4B, when the display apparatus 1 is not folded, ends of the protective film PFI, the display panel 50, the optical functional layer 42, the cover member 10, and the cover window CW may be separated, by a certain distance, from the avoidance groove 94b of the upper housing 94.

When the display apparatus 1 is folded as illustrated in FIG. 1B, a portion of the display apparatus 1 may shift in a direction perpendicular to the folding axis. In detail, as illustrated in FIG. 4B, when the display apparatus 1 is folded, at least one of the cover window CW, the cover member 10, the optical functional layer 42, the display panel 50, the protective film PFI, the panel protective member 41, the plate 60, the digitizer 70, the cushion layer 80, and the insulating film 89 may be shifted to a side surface of the housing 90. In the example of FIG. 4B, the distances that the illustrated end of each of the cover window CW, the cover member 10, the optical functional layer 42, the display panel 50, the protective film PFI, the panel protective member 41, the plate 60, the digitizer 70, the cushion layer 80, and the insulating film 89 shift may decrease from top to bottom.

When the display apparatus 1 is folded, the end of the second cover member 12 may be shifted along the inclined surface 94a. Here, a surface of the second cover member 12 may be curved, and thus, the second cover member 12 shifts along the inclined surface 94a. The avoidance groove 94b may limit the shifting path of the second cover member 12. Also, a portion of the second cover member 12 may remain in contact with the brush portion 96. In this case, shifting of the optical functional layer 42, the display panel 50, and the protective film PFI may be similar to the shifting of the second cover member 12. The ends of the panel protective member 41, the plate 60, the digitizer 70, the cushion layer 80, and the insulating film 89 may also shift toward the side surface of the housing 90. Here, the second cover member 12 may enter the avoidance groove 94b.

The second cover member 12, the optical functional layer 42, the display panel 50, and the protective film PFI may shift not only toward the side surface of the housing 90 but also toward a lower surface of the housing 90.

In this case, the shifting may bring at least one of the protective film PFI, the panel protective member 41, the plate 60, the digitizer 70, the cushion layer 80, and the insulating film 89 into contact with the elastic member 2, causing the shape of the elastic member 2 to change. For example, the elastic member 2 may have a ring-shaped cross-section as illustrated in FIG. 4A, but that cross-section may be changed to have a dent or protruding portion as illustrated in FIG. 4B.

When the display apparatus 1 is unfolded again to be flat, the elastic member 2 may apply a resilient force to at least one of the cover window CW, the cover member 10, the optical functional layer 42, the display panel 50, the protective film PFI, the panel protective member 41, the plate 60, the digitizer 70, the cushion layer 80, and the insulating film 89.

Thus, the when the display apparatus 1 is folded, at least one of the cover window CW, the cover member 10, the optical functional layer 42, the display panel 50, the protective film PFI, the panel protective member 41, the plate 60, the digitizer 70, the cushion layer 80, and the insulating film 89 may be prevented from contacting the housing 90.

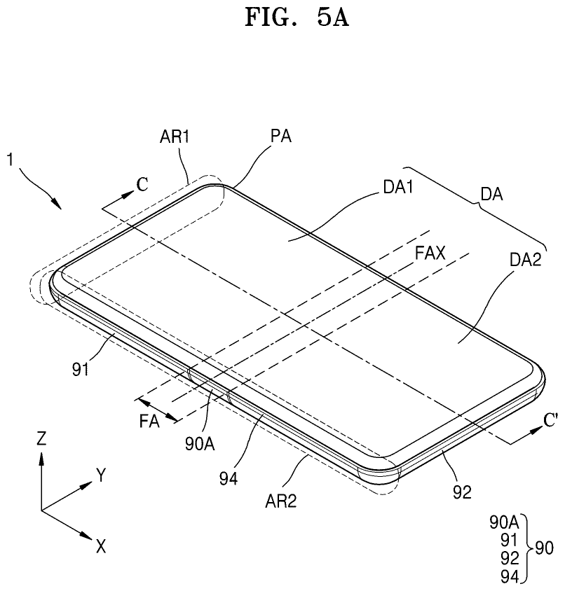

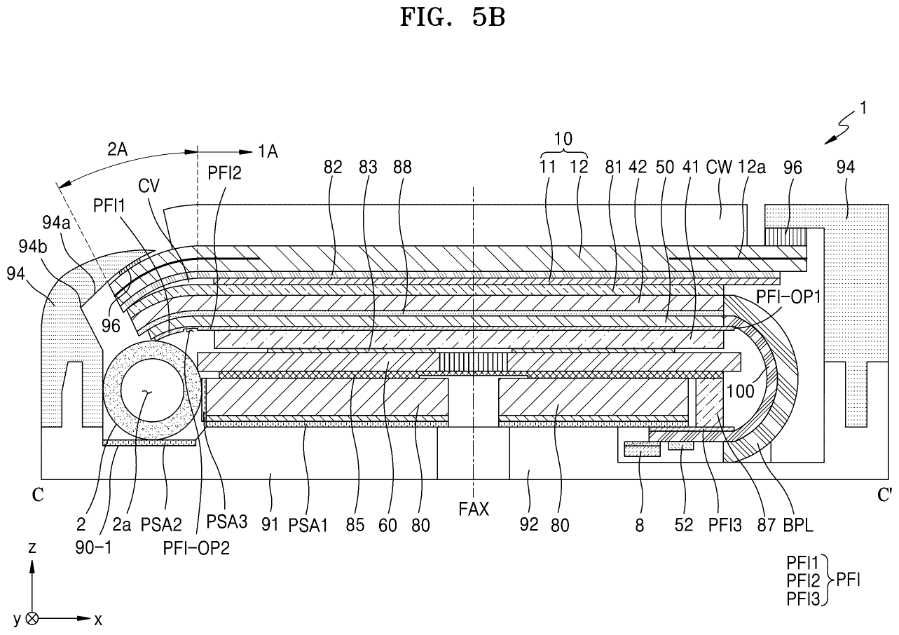

FIG. 5A is a schematic perspective view of the display apparatus 1 according to another embodiment. FIG. 5B is a schematic cross-sectional view of a portion of the display apparatus 1 taken along line C-C′ of FIG. 5A.

Referring to FIGS. 5A and 5B, the display apparatus 1 may include the display area DA and the peripheral area PA around the display area DA. According to an embodiment, the display apparatus 1 may include a folding area FA, and the display area DA may include a first display area DA1 and a second display area DA2 that are separated from each other with the folding area FA therebetween. Here, the display area DA, the folding area FA, and the peripheral area PA may be the same or substantially the same as described above with reference to FIG. 1A, and thus, their detailed descriptions are omitted in the following.

According to an embodiment, the display apparatus 1 may include the cover window CW, the cover member 10, the panel protective member 41, the optical functional layer 42, the display panel 50, the protective film PFI, the plate 60, the cushion layer 80, the insulating film 89, the housing 90, the brush portion 96, the elastic member 2, and a protective layer (not shown). Here, the cover member 10, the panel protective member 41, the optical functional layer 42, the display panel 50, the protective film PFI, the plate 60, the cushion layer 80, the insulating film 89, the brush portion 96, the elastic member 2, and the protective layer may be the same or substantially the same as described with reference to FIGS. 1A to 1C.

The cover member 10 may include the first cover member 11 and the second cover member 12, and the cover member adhesive layer 82 may be between the first cover member 11 and the second cover member 12. The first adhesive member 81 may be between the cover member 10 and the optical functional layer 42, and the fifth adhesive member 88 may be between the optical functional layer 42 and the display panel 50. The third adhesive member 85 may be between the plate 60 and the cushion layer 80, and the fourth adhesive member 87 may be on the third adhesive member 85. Also, the sixth adhesive member PSA1 may be between the insulating film 89 and the housing 90, the seventh adhesive member PSA2 may be between the elastic member 2 and the housing 90, and the eighth adhesive member PSA3 may be between the elastic member 2 and the cushion layer 80. Here, the mounting groove 90-1 may be provided in the housing 90 for mounting of the elastic member 2.

The second cover member 12 may include the first area 1A and the second area 2A with the second area 2A being adjacent to the first edge AR1. Here, the first area 1A may be entirely flat, and the entirety of the second area 2A may be inclined or curved. Also, the second cover member 12 may be flat or straight along the X direction or the Y direction at the second edge AR2, the edge which faces the second edge AR2, and the edge which faces the first edge AR1 of FIG. 1A. In this case, although not shown, a reinforcement layer may include a region adjacent to the second edge AR2 of the display apparatus 1, similarly to the embodiment shown in FIG. 1D. That is, the reinforcement layer may be between a side surface of at least one of the cover window CW, the cover member 10, the panel protective member 41, the optical functional layer 42, the display panel 50, the protective film PFI, the plate 60, the cushion layer 80, the insulating film 89, and the housing 90 and the housing 90. In this case, an upper surface of the first adhesive member 81, a lower surface of the cover member adhesive layer 82, and a side surface of the first cover member 11 may form a space CV.

The housing 90 may include the first portion 91, the second portion 92, the first hinge portion 90A, and the upper housing 94. Here, the first portion 91, the second portion 92, the first hinge portion 90A, and the upper housing 94 may be the same or substantially the same as described above with reference to FIGS. 1A to 1C, and thus, their detailed descriptions are omitted below.

The protective film PFI may include the first protective film PFI1, the second protective film PFI2, and the third protective film PFI3. Also, the protective film PFI may include the first opening area PFI-OP1 and the second opening area PFI-OP2. Here, the second opening area PFI-OP2 may be formed by removing only a portion of the protective film PFI. For example, the second opening area PFI-OP2 may include a groove in the protective film PFI. That is, the thickness of a portion of the protective film PFI, in which the second opening area PFI-OP2 is formed, may be less than the thickness of the first protective film PFI1 or the second protective film PFI2, in which the second opening area PFI-OP2 is not formed.

The fourth adhesive member 87 may be between the third protective film PFI3 and the plate 60, and the third protective film PFI3 may be at an end of the substrate 100. Here, the bending protective layer BPL may be arranged in a bending area of the substrate 100. Also, the display driver 52 may be at an end of the substrate 100 and may be connected to the flexible printed circuit board 8.

The expression “above” as used here denotes a direction from the display panel 50 toward the cover member 10, that is, a +Z direction, and the expression “below” denotes a direction from the display panel 50 toward the digitizer 70, that is, a −Z direction.

According to an embodiment, the display apparatus 1 may have a rectangular shape in a plan view. For example, the display apparatus 1 may have a rectangular planar shape having a long side extending in a first direction (an x direction) and a short side extending in a second direction (a y direction) crossing the first direction (the x direction), as illustrated in FIG. 1A. A corner at which the long side and the short side meet each other may be curved, i.e., may have a predetermined curvature, or may be right-angled. However, the display apparatus 1 is not limited to having the rectangular planar shape and may have other shapes, such as a polygonal shape, an oval shape, or an amorphous shape.

According to an embodiment, the display apparatus 1 may have various forms. For example, the display apparatus 1 may have a fixed shape. According to an embodiment, at least a portion of the display apparatus 1 may be folded. In this case, the display apparatus 1 may have an in-folding shape where the display apparatus 1 may be folded such that portions of the display area DA may face each other or may have an out-folding shape where the display apparatus 1 may be folded such that the display areas DA may be exposed to the outside. Hereinafter, for convenience of explanation, a case in which the display apparatus 1 may have the in-folding shape is mainly described.

According to an embodiment, the display apparatus 1 may be folded about (or based on) the folding axis FAX. In this case, when the display apparatus 1 is folded about (or based on) the folding axis FAX, the display apparatus 1 may occupy a reduced area, compared to when the display apparatus 1 is completely unfolded.

Thus, when the display apparatus 1 is completely unfolded, a large display screen may be realized, and when the display apparatus 1 is completely folded, the area of the display apparatus 1 may be reduced, and thus, the portability of the display apparatus 1 may be increased.

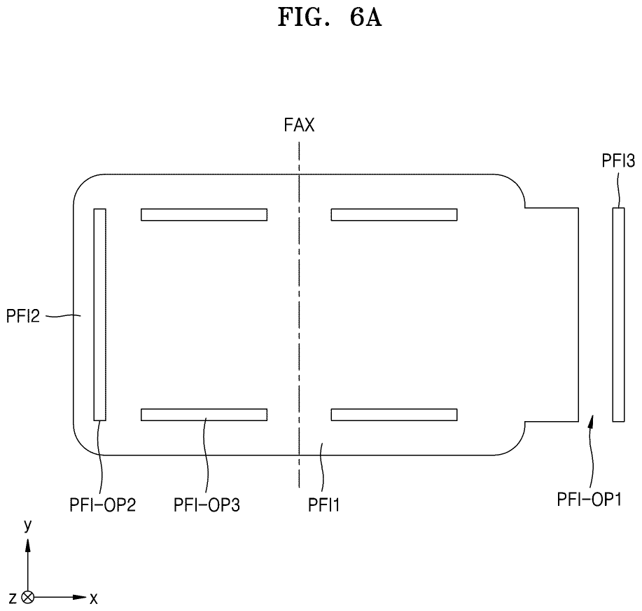

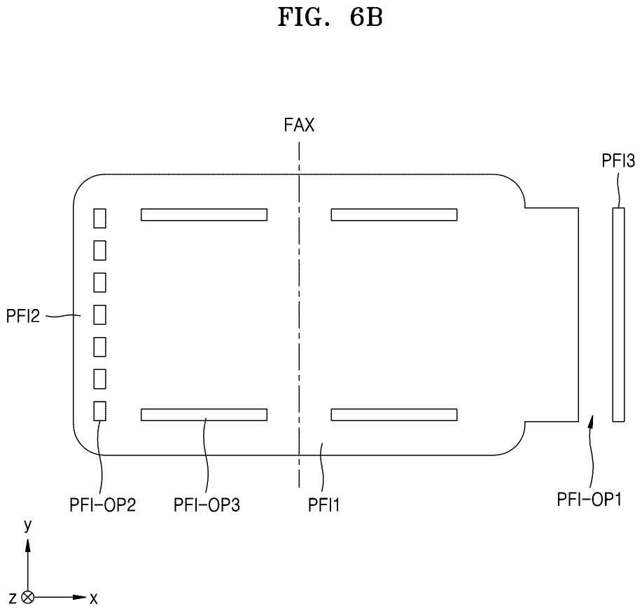

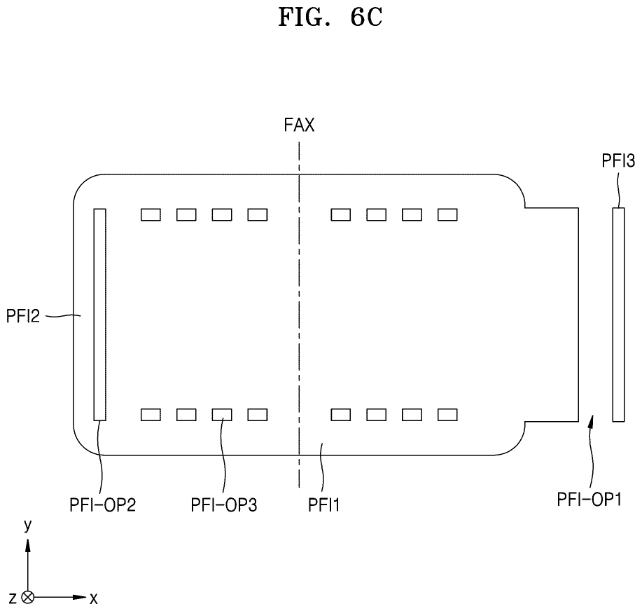

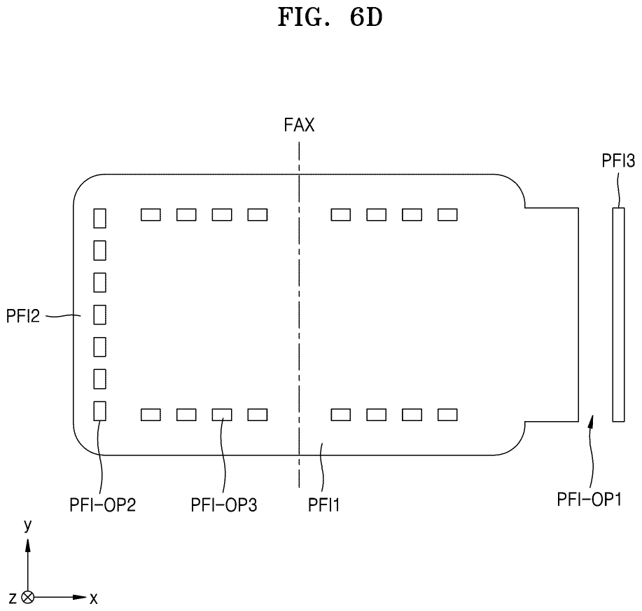

FIGS. 6A to 6D are schematic rear views of embodiments of the protective film PFI illustrated in FIG. 5B.

Referring to FIG. 6A, the protective film PFI may include the first protective film PFI1, the second protective film PFI2, and the third protective film PFI3. Also, the protective film PFI may include the first opening area PFI-OP1, the second opening area PFI-OP2, and the third opening area PFI-OP3. Here, the first protective film PFI1 and the second protective film PFI2 may be connected to each other, and the second opening area PFI-OP2 may be between the first protective film PFI1 and the second protective film PFI2. Also, the first protective film PFI1 and the third protective film PFI3 may be separated from each other, and the first opening area PFI-OP1 may be between the first protective film PFI1 and the third protective film PFI3. The second opening area PFI-OP2 may correspond to an area of the substrate 100 of the display panel 50 that is bent, and at which the bending protective layer BPL is located.

The second opening area PFI-OP2 may be long and straight opening in the region of the protective film PFI adjacent to the first edge AR1. For example, a lengthwise direction of the second opening area PFI-OP2 may be parallel with the folding axis FAX. Also, one third opening area PFI-OP3 or a pair of third opening areas PFI-OP3 may be in each of two areas bounded by the folding axis FAX. When one third opening area PFI-OP3 is arranged in one area, the one third opening area PFI-OP3 may be only in an area adjacent to one of two sides of the protective film PFI facing each other. According to another embodiment, when a pair of third opening areas PFI-OP3 are in one area, the third opening areas PFI-OP3 may include openings respectively adjacent to the facing sides. Here, the third opening areas PFI-OP3 may not overlap the folding axis FAX.

Referring to FIG. 6B, the second opening area PFI-OP2 may include multiple separate openings. Here, the separate opening forming the second opening area PFI-OP2 may be serially arranged. A direction in which the plurality of second opening areas PFI-OP2 are arranged may be in parallel with the folding axis FAX. The first opening area PFI-OP1 and the third opening area PFI-OP3 may be the same as described above with reference to FIG. 6A, and thus, their detailed descriptions are omitted here.

Referring to FIG. 6C, the third opening area PFI-OP3 may include multiple separated openings. For example, a group of the separated openings included in the third opening area PFI-OP3 may be arranged in each area of the protective film PFI bounded by the folding axis FAX. One group of the separated openings of the third opening area PFI-OP3 or a pair of groups of the separated openings of the third opening areas PFI-OP3 may be in each area. Also, the group of the separated openings of third opening areas PFI-OP3 may be linearly arranged in a direction perpendicular to the folding axis FAX. The first opening area PFI-OP1 and the third opening area PFI-OP3 may be the same as described above with reference to FIG. 6A, and thus, their detailed descriptions are omitted.

Referring to FIG. 6D, the second opening area PFI-OP2 and the third opening area PFI-OP3 may each include multiple separated openings. Here, the separated openings of the second opening area PFI-OP2 may be the same or substantially the same as described with reference to FIG. 6B, and the separated openings of the third opening area PFI-OP3 may be the same or substantially the same as described with reference to FIG. 6C. Also, the first opening area PFI-OP1 may be the same as described above with reference to FIG. 6A, and thus, its detailed description is omitted.

Also, although not shown, the third opening area PFI-OP3 may not be provided. In this case, the second opening area PFI-OP2 may have the same shape as illustrated in FIG. 6A or 6B.

The shapes of the second opening area PFI-OP2 and the third opening area PFI-OP3 may vary, rather than having the rectangular shape or the square shape described above. For example, although not shown, at least one of the second opening area PFI-OP2 and the third opening area PFI-OP3 may include an opening having an oval shape, a shape similar to a rectangular shape and having an edge having a concavo-convex shape, or a shape corresponding to a plurality of circles that are separated from each other.

The second opening area PFI-OP2 and the third opening area PFI-OP3 may include a groove or a hole. The second opening area PFI-OP2 and the third opening area PFI-OP3 may partially alleviate the rigidity of the protective film PFI.

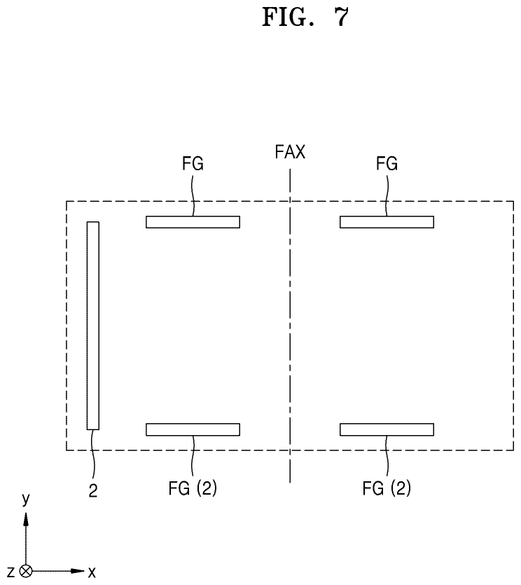

FIG. 7 is a schematic plan view of arrangement of the elastic member 2 and the reinforcement layer FG illustrated in FIG. 5B.

Referring to FIG. 7, the elastic member 2 may be adjacent to the first edge AR1 illustrated in FIG. 5A, and the reinforcement layer FG may include regions adjacent to the second edge AR2 illustrated in FIG. 5A. Here, the reinforcement layer FG may not overlap the folding axis FAX, and copies of the elastic member 2 may be used in place of the regions of the reinforcement layer FG. Also, the elastic member 2 may be integrally formed as illustrated in FIG. 7, and although not shown in FIG. 7, a plurality of elastic members 2 may be serially arranged to be separated from each other like the second opening areas PFI-OP2 illustrated in FIG. 6B. In this case, an additional member may not be between adjacent elastic members 2, and thus, in FIG. 6B, the elastic member 2 may not be arranged at the left side.

The reinforcement layer FG may include multiple regions in each area of the display apparatus 1 bounded by the folding axis FAX as illustrated in FIG. 7. In this case, the regions of the reinforcement layers FG in each area may be separated from each other like the third opening areas PFI-OP3 illustrated in FIG. 6C or FIG. 6D.

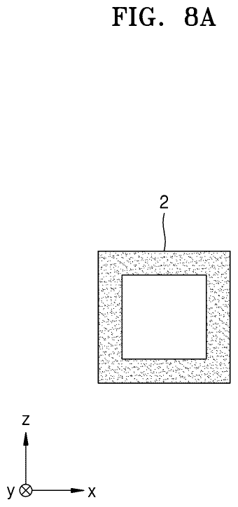

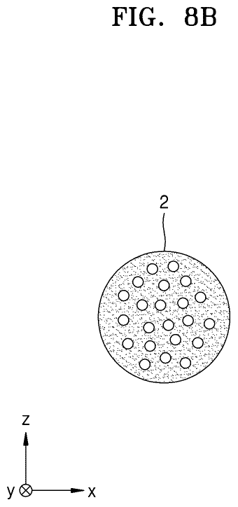

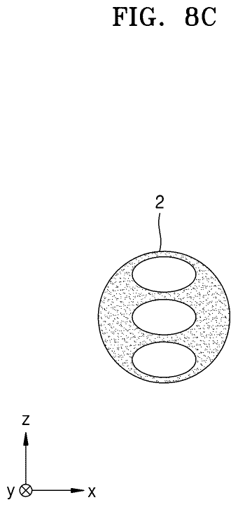

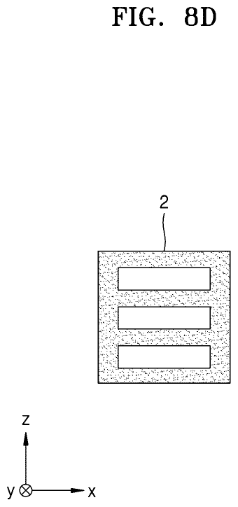

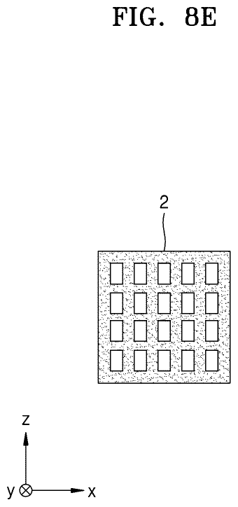

FIGS. 8A to 8E are cross-sectional views of embodiments of the elastic member 2 of a display apparatus.

Referring to FIG. 8A, the clastic member 2 may have various cross-sectional shapes. For example, the elastic member 2 may have a quadrangular cross-sectional shape. In the embodiment of FIG. 8A, the elastic member 2 has only one cavity.

Referring to FIG. 8B, the elastic member 2 may include a plurality of spaces. For example, the elastic member 2 may have a porous shape. Here, the spaces in the elastic member 2 may not be connected to the outside or may be connected to the outside. The elastic member 2 may include a sponge, etc. Here, FIG. 8B illustrates that all spaces in the elastic member 2 may have the same size. However, the spaces are not limited thereto and the size of one of the plurality of spaces may be different from the size of another of the plurality of spaces. Also, FIG. 8B also shows spaces in the elastic member 2 may have circular cross-sectional shapes. However, the spaces are not limited thereto and one or more of the plurality of spaces may have a polygonal cross-sectional shape, such as a triangular cross-sectional shape, an oval cross-sectional shape, an amorphous cross-sectional shape, or a more complex shape such as a star cross-sectional shape. FIG. 8B shows an embodiment in which all of the plurality of spaces in the elastic member 2 may have the same cross-sectional shapes. However, the spaces are not limited thereto and one of the plurality of spaces may have a different cross-sectional shape from another of the plurality of spaces.

Referring to FIG. 8C, the elastic member 2 may include at least one cavity. Here, the cavity may have an oval cross-sectional shape. Also, the elastic member 2 may include a plurality of cavities that are separated from each other.

Referring to FIG. 8D, the cavities of the elastic member 2 may have quadrangular cross-sectional shapes. Here, the plurality of cavities may be stacked in a height direction of the elastic member 2.

Referring to FIG. 8E, the elastic member 2 may include a plurality of cavities. Here, the plurality of cavities may be arranged to be separated from each other in columns and rows.

With respect to this aspect, the elastic member 2 may have a circular or quadrangular cross-sectional shape. However, the clastic member 2 is not limited thereto. For example, the elastic member 2 may include a polygonal cross-sectional shape, an oval cross-sectional shape, or an amorphous cross-sectional shape excluding the polygonal cross-sectional shape, a circular cross-sectional shape, and the oval cross-sectional shape. Also, the cross-sectional shape of the cavity is not limited thereto. The cavity may include a polygonal cross-sectional shape, an oval cross-sectional shape, or an amorphous cross-sectional shape excluding the polygonal cross-sectional shape, a circular cross-sectional shape, and the oval cross-sectional shape. Here, the cross-sectional shape may denote a cross-sectional shape taken along a direction perpendicular to a length or elongated direction of the elastic member 2. For example, the cross-sectional shape of the clastic member 2 and the cross-sectional shape of the cavity may be taken in a direction perpendicular to a lengthwise direction of the elastic member 2.

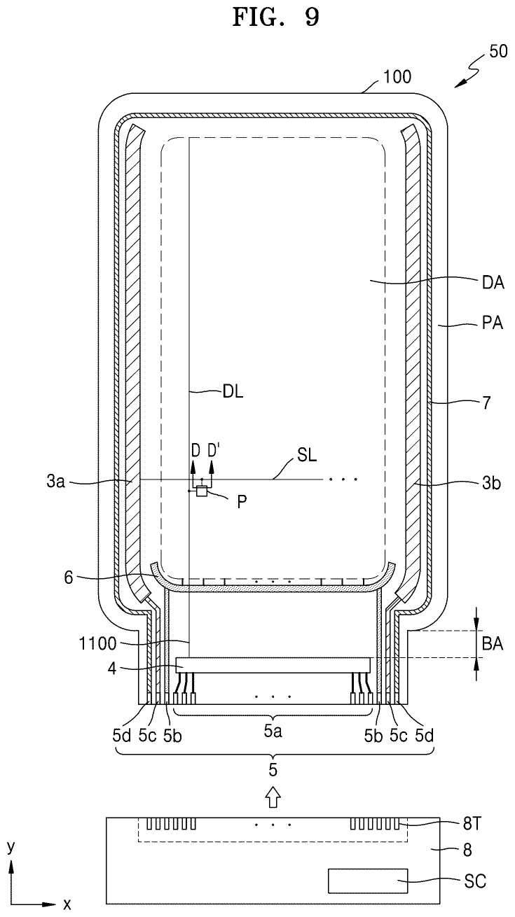

FIG. 9 is a schematic plan view of an embodiment of the display panel 50 illustrated in FIG. 1B or 5B.

Referring to FIG. 9, a display apparatus (not shown) may include the display panel 50 and the flexible printed circuit board 8. The display panel 50 may emit red, green, or blue light from a light-emitting diode at a position corresponding to any of the sub-pixels P in the display area DA. The display area DA may contain signal lines, for example, data lines DL and scan lines SL, electrically connected to transistors and storage capacitors electrically connected to the light-emitting diodes in the display area DA. The data lines DL may extend in a y direction in the display area DA and the scan lines SL may extend in an x direction in an embodiment of the display area DA.

The peripheral area PA may be outside the display area DA and may entirely surround the display area DA.

First and second scan drivers 3a and 3b may be arranged in the peripheral area PA and may be electrically connected to the scan lines SL. According to an embodiment, some of the scan lines SL may be electrically connected to the first scan driver 3a, and the others may be electrically connected to the second scan driver 3b. The first and second scan drivers 3a and 3b may be configured to generate a scan signal, and the generated scan signal may be transmitted through the scan lines SL to the transistors electrically connected to the light-emitting diodes.

The first and second scan drivers 3a and 3b may be on both sides of the display area DA. For example, as illustrated in FIG. 9, the first scan driver 3a may be to the left of the display area DA, and the second scan driver 3b may to the right of the display area DA. According to another embodiment, any one of the first and second drivers 3a and 3b may be omitted.

A driving voltage supply line 6 may be in the peripheral area PA. The driving voltage supply line 6 may be between the display area DA and a side area of the substrate 100 containing a terminal portion 5.

A common voltage supply line 7 may be in the peripheral area PA and may have a loop shape extending partly around the display area DA and having an open side. The common voltage supply line 7 may generally have a U-shape as illustrated in FIG. 9. The common voltage supply line 7 may extend along sides of substrate 100 except for the side of the substrate 100 where the terminal portion 5 resides, and thus, the first scan driver 3a may be between a portion of the common voltage supply line 7 and the display area DA, and the second scan driver 3b may be between another portion of the common voltage supply line 7 and the display area DA.

An integrated circuit device 4 may be arranged in the peripheral area PA. The integrated circuit device 4 may be between the display area and the area of the substrate 100 containing the terminal portion 5. The integrated circuit device 4 may include a data driver. In the following, the integrated circuit device 4 may denote a data driver. The integrated circuit device 4 may be electrically connected to a pad terminal disposed therebelow. A data signal generated by the integrated circuit device 4, for example, the data driver, may be transmitted to a signal line, for example, the data line DL, arranged in the display area DA, through a connection line 1100 in a fan-out area. The fan-out area may be a portion of the peripheral area PA and may correspond to an area between the integrated circuit device 4 and the display area DA.

The terminal portion 5 may include terminals 5a, 5b, 5c, and 5d. The terminals 5a to 5d may not be covered by an insulating layer, may be thus exposed, and may be electrically connected to a controller SC arranged on the flexible printed circuit board 8. The flexible printed circuit board 8 may include counter terminals 8T corresponding to the terminal portion 5. The counter terminals 8T of the flexible printed circuit board 8 may be electrically connected to the terminals 5a to 5d. The controller SC may generate a control signal for controlling the first and second scan drivers 3a and 3b and the integrated circuit device 4, and the generated control signal may be transmitted to the first and second scan drivers 3a and 3b and the integrated circuit device 4 through the terminals 5a and 5c. The controller SC may transmit a driving voltage and a common voltage to the driving voltage supply line 6 and the common voltage supply line 7, respectively, through the terminals 5b and 5d. According to an embodiment, at least a portion of the display panel 50 may be bent. For example, a portion of the display panel 50 may be bent such that a portion of the peripheral area PA containing the integrated circuit device 4, may be at a rear surface of the display area DA. Here, the display panel 50 may include a bending area BA, which is a bent portion of the peripheral area PA. The bending area BA may be between the display area DA and the integrated circuit device 4.

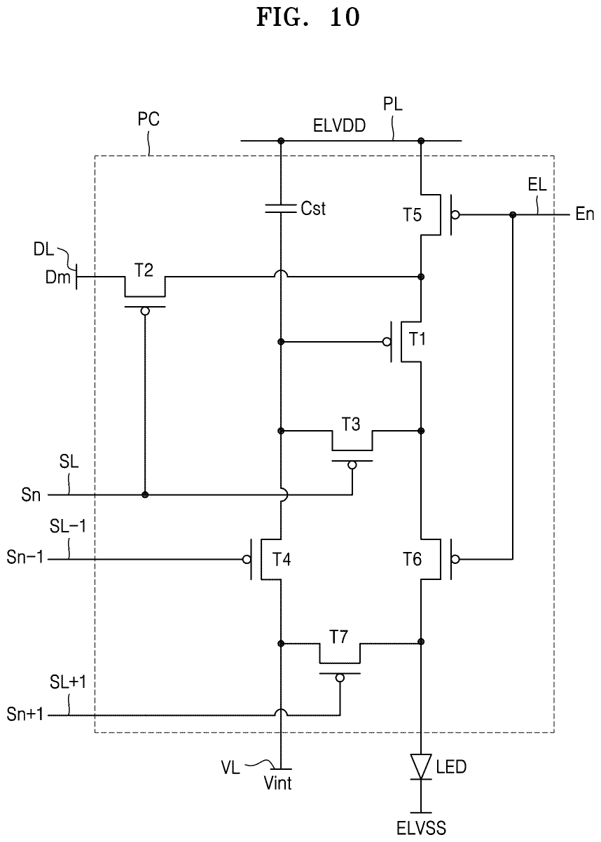

FIG. 10 shows an equivalent circuit diagram of a sub-pixel circuit PC electrically connected to a light-emitting diode LED included in a display apparatus according to an embodiment.

Referring to FIG. 10, as described above with reference to FIG. 9, each sub-pixel P (FIG. 9) may emit light by using the light-emitting diode LED. The light-emitting diode LED may be electrically connected to the sub-pixel circuit PC.

The sub-pixel circuit PC may include a first thin-film transistor T1, a second thin-film transistor T2, a third thin-film transistor T3, a fourth thin-film transistor T4, a fifth thin-film transistor T5, a sixth thin-film transistor T6, a seventh thin-film transistor T7, and a storage capacitor Cst.

The second thin film transistor T2 may include a switching thin film transistor, may be connected to a scan line SL and a data line DL, and may be configured to transmit, to the first thin film transistor T1, a data voltage (or a data signal Dm) input from the data line DL, based on a switching voltage (or a switching signal Sn) input from the scan line SL. The storage capacitor Cst may be connected to the first thin-film transistor T1 and a driving voltage line PL and may be configured to store a voltage corresponding to the difference between a driving voltage ELVDD supplied to the driving voltage line PL and a voltage received from the second thin-film transistor T2 with compensation for the threshold voltage of the first thin-film transistor T1.

The first thin-film transistor T1 may include a driving thin-film transistor, may be connected to the driving voltage line PL and the storage capacitor Cst, and may be configured to control a driving current flowing from the driving voltage line PL through the light-emitting diode LED according to a value of the voltage stored in the storage capacitor Cst. The light-emitting diode LED may emit light having a brightness that depends on the driving current. A second electrode (for example, a cathode) of the light-emitting diode LED may receive a common voltage ELVSS.

The third thin-film transistor T3 may include a compensation thin-film transistor, and a gate electrode of the third thin-film transistor T3 may be connected to the scan line SL. A source electrode (or a drain electrode) of the third thin-film transistor T3 may be connected to a drain electrode (or a source electrode) of the first thin-film transistor T1 and may be connected to a first electrode of the light-emitting diode LED through the sixth thin-film transistor T6. The drain electrode (or the source electrode) of the third thin-film transistor T3 may be connected to any or all of one electrode of the storage capacitor Cst, a source electrode (or a drain electrode) of the fourth thin-film transistor T4, and a gate electrode of the first thin-film transistor T1. The third thin-film transistor T3 may be turned on according to the scan signal Sn received through the scan line SL and may connect the gate electrode and the drain electrode of the first thin-film transistor T1 to each other to diode-connect the first thin-film transistor T1.

The fourth thin-film transistor T4 may include an initialization thin-film transistor, and a gate electrode of the fourth thin-film transistor T4 may be connected to a previous scan line SL−1. A drain electrode (or a source electrode) of the fourth thin-film transistor T4 may be connected to an initialization voltage line VL. The source electrode (or the drain electrode) of the fourth thin-film transistor T4 may be connected to any or all of one electrode of the storage capacitor Cst, the drain electrode (or the source electrode) of the third thin-film transistor T3, and the gate electrode of the first thin-film transistor T1. The fourth thin-film transistor T4 may be turned on in response to a previous scan signal Sn−1 received through the previous scan line SL−1 and may perform an initialization operation of initializing a voltage of the gate electrode of the first thin-film transistor T1 by transmitting an initialization voltage Vint to the gate electrode of the first thin-film transistor T1.

The fifth thin-film transistor T5 may include an operation control thin-film transistor, and a gate electrode of the fifth thin-film transistor T5 may be connected to an emission control line EL. A source electrode (or a drain electrode) of the fifth thin-film transistor T5 may be connected to the driving voltage line PL. The drain electrode (or the source electrode) of the fifth thin-film transistor T5 may be connected to the source electrode (or the drain electrode) of the first thin-film transistor T1 and a drain electrode (or a source electrode) of the second thin-film transistor T2.

The sixth thin-film transistor T6 may include an emission control thin-film transistor, and a gate electrode of the sixth thin-film transistor T6 may be connected to the emission control line EL. A source electrode (or a drain electrode) of the sixth thin-film transistor T6 may be connected to the drain electrode (or the source electrode) of the first thin-film transistor T1 and the source electrode (or the drain electrode) of the third thin-film transistor T3. The drain electrode (or the source electrode) of the sixth thin-film transistor T6 may be electrically connected to the first electrode of the light-emitting diode LED. The fifth thin-film transistor T5 and the sixth thin-film transistor T6 may be simultaneously turned on in response to an emission control signal En received through the emission control line EL so that the driving voltage ELVDD may be transmitted through the first thin-film transistor T1 to the light-emitting diode LED and the driving current may flow in the light-emitting diode LED.

The seventh transistor T7 may include an initialization thin-film transistor configured to initialize the first electrode of the light-emitting diode LED. A gate electrode of the seventh thin-film transistor T7 may be connected to a next scan line SL+1. A source electrode (or a drain electrode) of the seventh thin-film transistor T7 may be electrically connected to the first electrode of the light-emitting diode LED. The drain electrode (or the source electrode) of the seventh thin-film transistor T7 may be connected to the initialization voltage line VL. The seventh thin-film transistor T7 may be turned on in response to a next scan signal Sn+1 received through the next scan line SL+1 and may initialize the first electrode of the light-emitting diode LED.

FIG. 10 illustrates that the fourth thin-film transistor T4 and the seventh thin-film transistor T7 may be connected to the previous scan line SL−1 and the next scan line SL+1, respectively. However, according to another embodiment, both of the fourth thin-film transistor T4 and the seventh thin-film transistor T7 may be connected to the previous scan line SLn−1 and may be driven according to the previous scan signal Sn−1.

The other electrode of the storage capacitor Cst may be connected to the driving voltage line PL. One electrode of the storage capacitor Cst may be connected to all of the gate electrode of the first thin-film transistor T1, the drain electrode (or the source electrode) of the third thin-film transistor T3, and the source electrode (or the drain electrode) of the fourth thin-film transistor T4.

The second electrode (for example, the cathode) of the light-emitting diode LED may receive the common voltage ELVSS. The light-emitting diode LED may emit light by receiving the driving current from the first thin-film transistor T1.

The light-emitting diode LED, in one embodiment, may be an organic light-emitting diode including an organic material as a light-emitting material. According to another embodiment, the light-emitting diode LED may correspond to an inorganic light-emitting diode including an inorganic material. The inorganic light-emitting diode may include a PN junction diode including inorganic semiconductor-based materials. When a voltage is applied to the PN junction diode in a normal direction, holes and electrons may be injected into the PN junction diode and energy generated by recombination of the holes and the electrons may be converted into light energy, and thus, light of a certain color may be emitted. The inorganic light-emitting diode described above may have a width that is several to hundreds of micrometers or several to hundreds of nanometers. According to some embodiments, the light-emitting diode LED may include a quantum dot light-emitting diode. As described above, an emission layer of the light-emitting diode LED may include an organic material, an inorganic material, quantum dots, an organic material and quantum dots, or an inorganic material and quantum dots. Hereinafter, for convenience of explanation, the example in which the light-emitting diode LED includes an organic light-emitting diode is described.

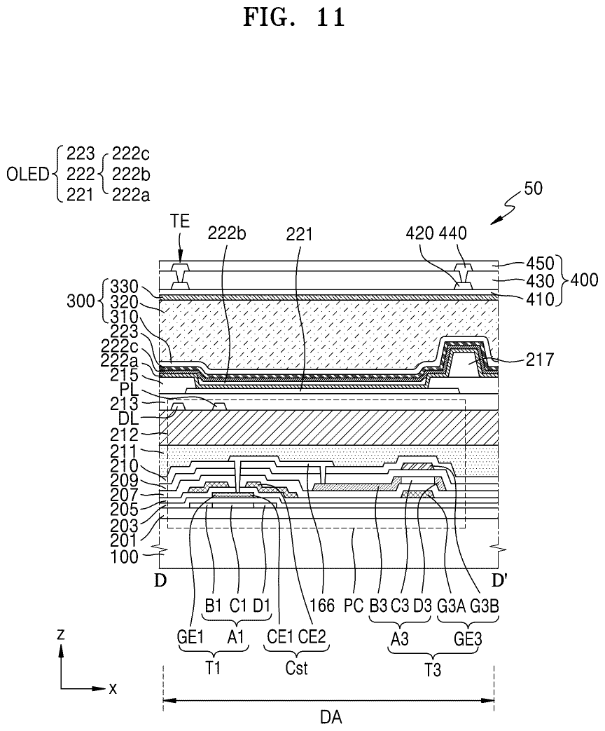

FIG. 11 is a schematic cross-sectional view of a portion of the display panel 50 taken along line D-D′ of FIG. 9.

Referring to FIG. 11, the display panel 50 may include the sub-pixel circuit PC and the light-emitting diode in the display area DA of the display panel 50. Here, the light-emitting diode may include an organic light-emitting diode OLED.

The substrate 100 may include glass materials or polymer resins. According to an embodiment, the substrate 100 may have a stack structure of a base layer including polymer resins and a barrier layer including an inorganic insulating material such as silicon oxide or silicon nitride. When the substrate 100 includes the stack structure including the base layer including the polymer resins and the barrier layer including the inorganic insulating material as described above, the display apparatus 1 may have improved flexibility, and thus, the display apparatus 1 may be foldable, as described above with reference to FIGS. 1A and 1B.

The polymer resins may include polyether sulfone, polyarylate, polyether imide, polyethylene naphthalate, polyethylene terephthalate, polyphenylene sulfide, polyimide, polycarbonate, cellulose triacetate, or cellulose acetate propionate.

The sub-pixel circuit PC may be formed on the substrate 100, and the light-emitting diode, for example, the organic light-emitting diode OLED, may be formed on the sub-pixel circuit PC.

Before forming the sub-pixel circuit PC on the substrate 100, a buffer layer 201 for preventing the penetration of impurities into the sub-pixel circuit PC may be formed on the substrate 100. The buffer layer 201 may include an inorganic insulating material, such as silicon nitride, silicon oxynitride, and silicon oxide, and may include a single-layered or layered structure including the inorganic insulating material described above.

The sub-pixel circuit PC may include the plurality of transistors and the storage capacitor as described above with reference to FIG. 10. With respect to this aspect, FIG. 11 illustrates the first thin-film transistor T1, the third thin-film transistor T3, and the storage capacitor Cst.

The first thin-film transistor T1 may include a semiconductor layer (hereinafter, referred to as a first semiconductor layer A1) on the buffer layer 201 and a gate electrode (hereinafter, referred to as a first gate electrode GE1) overlapping a channel area C1 of the first semiconductor layer A1. The first semiconductor layer A1 may include a silicon-based semiconductor material, for example, polysilicon. The first semiconductor layer A1 may include the channel area C1 and a first area B1 and a second area DI respectively on opposite sides of the channel area C1. The first area B1 and the second area DI may include more highly concentrated impurities than does the channel area C1, and any one of the first area B1 and the second area DI may correspond to a source area, and the other may correspond to a drain area.

A first gate insulating layer 203 may be between the first semiconductor layer A1 and the first gate electrode GE1. The first gate insulating layer 203 may include an inorganic insulating material, such as silicon oxide, silicon nitride, and silicon oxynitride, and may include a single-layered or layered structure including the inorganic insulating material described above.

The first gate electrode GE1 may include a conductive material including Mo, Al, Cu, Ti, etc. and may include a single-layered or layered structure including the conductive material described above.

The storage capacitor Cst may include a lower electrode CE1 and an upper electrode CE2 overlapping each other. According to an embodiment, the lower electrode CE1 of the storage capacitor Cst may include the first gate electrode GE1. In other words, the first gate electrode GE1 may include the lower electrode CE1 of the storage capacitor Cst. For example, the first gate electrode GE1 and the lower electrode CE1 of the storage capacitor Cst may be integrally formed with each other.

A first interlayer insulating layer 205 may be disposed between the lower electrode CE1 and the upper electrode CE2 of the storage capacitor Cst. The first interlayer insulating layer 205 may include an inorganic insulating material, such as silicon oxide, silicon nitride, and silicon oxynitride, and may include a single-layered or layered structure including the inorganic insulating material described above.

The upper electrode CE2 of the storage capacitor Cst may include a low-resistance conductive material, such as Mo, Al, Cu, and/or Ti, and may include a single-layered or layered structure including the material described above.

A second interlayer insulating layer 207 may be on the storage capacitor Cst. The second interlayer insulating layer 207 may include an inorganic insulating material, such as silicon oxide, silicon nitride, and silicon oxynitride, and may include a single-layered or layered structure including the inorganic insulating material described above.

A semiconductor layer (hereinafter, referred to as a third semiconductor layer A3) of the third thin-film transistor T3 may be disposed on the second interlayer insulating layer 207. The third semiconductor layer A3 may include an oxide-based semiconductor material. For example, the third semiconductor layer A3 may include a Zn oxide-based material, for example, a Zn oxide, an In—Zn oxide, a Ga—In—Zn oxide, etc. According to some embodiments, the third semiconductor layer A3 may include a semiconductor including In—Ga—Zn—O (IGZO), In—Sn—Zn—O (ITZO), or In—Ga—Sn—Zn—O (IGTZO), in which a metal, such as In, Ga, or Sn, is included in ZnO.

The third semiconductor layer A3 may include a channel area C3 and a first area B3 and a second area D3 respectively on opposite sides of the channel area C3. Any one of the first area B3 and the second area D3 may correspond to a source area, and the other may correspond to a drain area.

The third thin-film transistor T3 may include a gate electrode (hereinafter, referred to as a third gate electrode GE3) overlapping the channel area C3 of the third semiconductor layer A3. The third gate electrode GE3 may have a dual gate structure including a lower gate electrode G3A below the third semiconductor layer A3 and an upper gate electrode G3B above the channel area C3.

The lower gate electrode G3A may be on the same layer (for example, the first interlayer insulating layer 205) as the upper electrode CE2 of the storage capacitor Cst. The lower gate electrode G3A may include the same material as the upper electrode CE2 of the storage capacitor Cst.

The upper gate electrode G3B may be above the third semiconductor layer A3 with a second gate insulating layer 209 therebetween. The second gate insulating layer 209 may include an inorganic insulating material, such as silicon oxide, silicon nitride, and silicon oxynitride, and may include a single-layered or layered structure including the inorganic insulating material described above.

A third interlayer insulating layer 210 may be disposed on the upper gate electrode G3B. The third interlayer insulating layer 210 may include an inorganic insulating material, such as silicon oxynitride, and may include a single-layered or layered structure including the inorganic insulating material described above.

FIG. 11 illustrates the first thin-film transistor T1 and the third thin-film transistor T3 from among the plurality of thin-film transistors described with reference to FIG. 10 and illustrates that the first semiconductor layer A1 and the third semiconductor layer A3 are disposed on different layers. However, the disclosure is not limited thereto.

The second, fifth, sixth, and seventh thin-film transistors T2, T5, T6, and T7 described with reference to FIG. 10 may have the same structure as the first thin-film transistor T1 described with reference to FIG. 11. For example, each of the second, fifth, sixth, and seventh thin-film transistors T2, T5, T6, and T7 (FIG. 10) may include a semiconductor layer disposed on the same layer as the first semiconductor layer A1 of the first thin-film transistor T1 and a gate electrode disposed on the same layer as the first gate electrode GE1 of the first thin-film transistor T1. The semiconductor layers of the second, fifth, sixth, and seventh thin-film transistors T2, T5, T6, and T7 (FIG. 10) may be integrally connected with the first semiconductor layer A1.

The fourth thin-film transistor T4 described with reference to FIG. 10 may have the same structure as the third thin-film transistor T3 described with reference to FIG. 11. For example, the fourth thin-film transistor T4 may include a semiconductor layer disposed on the same layer as the third semiconductor layer A3 of the third thin-film transistor T3 and a gate electrode formed on the same layer as the third gate electrode GE3 of the third thin-film transistor T3. The semiconductor layer of the fourth thin-film transistor T4 and the third semiconductor layer A3 of the third thin-film transistor T3 may be integrally connected with each other.

The first thin-film transistor T1 and the third thin-film transistor T3 may be electrically connected to each other through a node connection line 166. The node connection line 166 may be disposed on the third interlayer insulating layer 210. A side of the node connection line 166 may be connected to the first gate electrode GE1 of the first thin-film transistor T1, and the other side of the node connection line 166 may be connected to the third semiconductor layer A3 of the third thin-film transistor T3.

The node connection line 166 may include Al, Cu, and/or Ti and may include a single layer or layers including the material described above. For example, the node connection line 166 may have a triple-layered structure of a Ti layer/an Al layer/a Ti layer.

A first organic insulating layer 211 may be on the node connection line 166. The first organic insulating layer 211 may include an organic insulating material. The organic insulating material may include acryl, benzocyclobutene (BCB), polyimide, or hexamethyldisiloxane (HMDSO).

A second organic insulating layer 212 may be on the first organic insulating layer 211. Here, the second organic insulating layer 212 may include the same or substantially the same material as the first organic insulating layer 211. Also, the second organic insulating layer 212 may be integrally formed with the first organic insulating layer 211 or the second organic insulating layer 212 may be separately formed from the first organic insulating layer 211 and may be stacked on the first organic insulating layer 211.

A data line DL and a driving voltage line PL may be on the first organic insulating layer 211 or the second organic insulating layer 212 and may be covered by the second organic insulating layer 212 or the third organic insulating layer 213. Hereinafter, for convenience of explanation, it is described in detail that the data line DL and the driving voltage line PL may be disposed on the second organic insulating layer 212 and covered by the third organic insulating layer 213.

The data line DL and the driving voltage line PL may include Al, Cu, and/or Ti and may include a single layer or layers including the material described above. For example, the data line DL and the driving voltage line PL may have a triple-layered structure of a Ti layer/an Al layer/a Ti layer.

The third organic insulating layer 213 may include an organic insulating material, such as acryl, BCB, polyimide, and/or HMDSO. FIG. 11 illustrates that the data line DL and the driving voltage line PL may be on the first organic insulating layer 211. However, the disclosure is not limited thereto. According to another embodiment, any one of the data line DL and the driving voltage line PL may be on the same layer as the node connection line 166, for example, on the third interlayer insulating layer 210.

The light-emitting diode, for example, the organic light-emitting diode OLED, may be on the third organic insulating layer 213.

A first electrode 221 of the organic light-emitting diode OLED may include a reflective layer including Ag, Mg, Al, Pt, Pd, Au, Ni, Nd, Ir, Cr, or a compound thereof. According to another embodiment, the first electrode 221 may further include a conductive oxide layer above and/or below the reflective layer described above. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). According to an embodiment, the first electrode 221 may have a triple-layered structure of ITO/Ag/ITO layers.

A bank layer 215 may be on the first electrode 221. The bank layer 215 may include an opening overlapping the first electrode 221 and may cover an edge of the first electrode 221. The bank layer 215 may include an organic insulating material such as polyimide.

An intermediate layer 222 may include an emission layer 222b. The intermediate layer 222 may include a first functional layer 222a below the emission layer 222b and/or a second functional layer 222c above the emission layer 222b. The emission layer 222b may include a high molecular-weight or low molecular-weight organic material capable of emitting light of a certain color. The second functional layer 222c may include an electron transport layer (ETL) and/or an electron injection layer (EIL). The first functional layer 222a and the second functional layer 222c may include an organic material.

The second electrode 223 may include a conductive material having a low work function. For example, the second electrode 223 may include a transparent (semi-transparent) layer including Ag, Mg, Al, Pt, Pd, Au, Ni, Nd, Ir, Cr, Li, Ca, or an alloy thereof. Alternatively, the second electrode 223 may further include a layer, such as ITO, IZO, ZnO, or In₂O₃, on the (semi) transparent layer including the material described above.

The emission layer 222b may be formed in the display area DA to overlap the first electrode 221 through the opening of the bank layer 215. However, the first functional layer 222a, the second functional layer 222c, and the second electrode 223 may entirely cover the display area DA.

A spacer 217 may be formed on the bank layer 215. The spacer 217 may be formed together with the bank layer 215 by the same process as the bank layer 215 or separately from the bank layer 215 by a separate process. According to an embodiment, the spacer 217 may include an organic insulating material such as polyimide. Alternatively, the bank layer 215 may include an organic insulating material including a light-blocking dye and the spacer 217 may include an organic insulating material such as polyimide.

The organic light-emitting diode 220 may be covered by an encapsulation layer 300. The encapsulation layer 300 may include at least one organic encapsulation layer and at least one inorganic encapsulation layer. According to an embodiment, FIG. 11 illustrates that the encapsulation layer 300 may include a first inorganic encapsulation layer 310, a second inorganic encapsulation layer 330, and an organic encapsulation layer 320 between the first and second inorganic encapsulation layers 310 and 330.

The first and second inorganic encapsulation layers 310 and 330 may include one or more inorganic materials from among aluminum oxide (Al₂O₃), titanium oxide (TiO), tantalum oxide (TA₂O₅), hafnium oxide (HfO₂), zinc oxide (ZnO), silicon oxide (SiOₓ), silicon nitride (SiNₓ), and silicon oxynitride (SiON). The first and second inorganic encapsulation layers 310 and 330 may include a single layer or layers including the material described above. The organic encapsulation layer 320 may include a polymer-based material. The polymer-based material may include acryl-based resins, epoxy-based resins, polyimide, polyethylene, etc. According to an embodiment, the organic encapsulation layer 320 may include acrylate.

Thicknesses of the first and second inorganic encapsulation layers 310 and 330 may be different from each other. The thickness of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first and second inorganic encapsulation layer 310 and 330 may be the same as each other.

An input sensing layer 400 may be disposed on the encapsulation layer 300. The input sensing layer 400 may include touch electrodes TE arranged in the display area DA and at least one touch insulating layer. With respect to this aspect, FIG. 11 illustrates that the input sensing layer 400 may include a first touch insulating layer 410 on the second inorganic encapsulation layer 330, a first conductive line 420 on the first touch insulating layer 410, a second touch insulating layer 430 on the first conductive line 420, a second conductive line 440 on the second touch insulating layer 430, and a third touch insulating layer 450 on the second conductive line 440.

Each of the first touch insulating layer 410, the second touch insulating layer 430, and the third touch insulating layer 450 may include an inorganic insulating material and/or an organic insulating material. According to an embodiment, the first touch insulating layer 410 and the second touch insulating layer 430 may include an inorganic insulating material such as silicon oxide, silicon nitride, and/or silicon oxynitride and the third touch insulating layer 450 may include an organic insulating material. At least one of the first touch insulating layer 410, the second touch insulating layer 430, and the third touch insulating layer 450 may extend from the display area DA into the peripheral area PA.

A touch electrode TE of the input sensing layer 400 may include a structure in which the first conductive line 420 and the second conductive line 440 are connected to each other. Alternatively, the touch electrode TE may include any one of the first conductive line 420 and the second conductive line 440, and in this case, the second touch insulating layer 430 may be omitted.

Each of the first conductive line 420 and the second conductive line 440 may include Al, Cu, and/or Ti and may include a single layer or layers including the materials described above. For example, each of the first conductive line 420 and the second conductive line 440 may have a triple-layered structure of a Ti layer/an Al layer/a Ti layer.

As described above, according to the display apparatus according to the one or more of the above embodiments, fracture of an edge portion due to external shocks may be reduced.

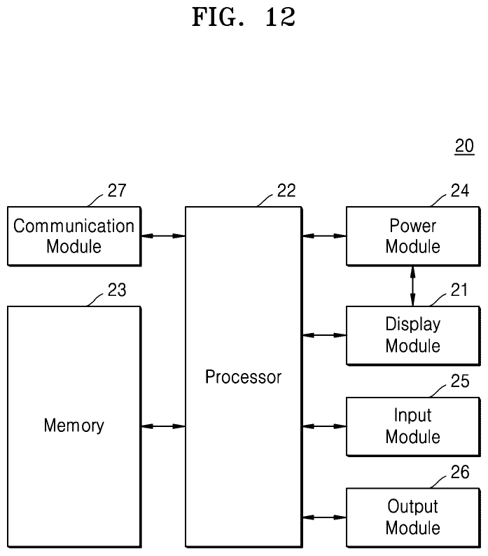

FIG. 12 is a block diagram of an electronic device 20 according to an embodiment.

Referring to FIG. 12, the electronic device 20 according to an embodiment may include a display module 21 including a display panel, a processor 22, a memory 23, and a power module 24.

The processor 22 may include at least one of a central processing unit (CPU), an application processor (AP), a graphics processing unit (GPU), a communication processor (CP), an image signal processor (ISP), and a controller. According to an embodiment, the processor 22 may be provided by being divided into two or more processors in a functional or structural perspective. For example, the processor 22 may include a main processor as a first driving chip including a CPU and an auxiliary processor as a second driving chip including a controller configured to receive an image signal from the main processor and process the image signal according to the interface specifications of the display module 21.

The memory 23 may include at least one of a non-volatile memory and a volatile memory. The memory 23 may store data information necessary for operations of the processor 22 or the display module 21. When the processor 22 executes an application stored in the memory 23, an image data signal and/or an input control signal may be transmitted to the display module 21, and the display module 21 may be configured to process the received signal and output image information through a display screen.

The power module 24 may include a power supply module, such as a power adaptor or a battery device, and a power conversion module configured to convert a power supply from the power supply module and generate power necessary for operations of the electronic device 20. The power conversion by the power conversion module may include direct current DC-DC conversion, alternating current AC-DC conversion, and DC-AC conversion, but is not limited thereto.

The electronic device 20 may further include an input module 25, a non-image output module 26, and/or a communication module 27.

The input module 25 may provide input information to the processor 22 and/or the display module 21. The input module 25 may include not only a physical button, a keyboard, and a microphone, but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors, such as a blood-pressure sensor, a blood-sugar sensor, an electrocardiogram sensor, a heart rate sensor, etc.

The non-image output module 26 may receive information except for an image from the processor 22 and provide the information to a user. Examples of the non-image output module 26 may include a sound module, a haptic module, a light-emission module, etc. and may also include other functionally intrinsic modules (for example, a cooling module of a refrigerator, etc.) of an electronic device.

The communication module 27 may be configured to perform transmission and reception of information between the electronic device 20 and an external device and may include a receiver and a transmitter. The communication module 27 may include various wireless communication modules, such as a mobile communication module, a WiFi module, a Bluetooth module, etc., or various wired communication modules.

The components of the electronic device 20 described above may be included in the display apparatus 1 according to the embodiments described above. Also, some of separate modules functionally included in one module may be included in the display apparatus 1 and the others may be provided separately from the display apparatus 1. For example, the display apparatus 1 may include the display module 21, and the processor 22, the memory 23, and the power module 24 may be provided in the electronic device 20, rather than the display apparatus 1, as other devices. As another example, the power module 24 may be provided in the display apparatus 1 and may provide a power supply to the processor 22 and the memory 23 which are provided in the electronic device 20, rather than the display apparatus 1. However, the disclosure is not limited thereto.

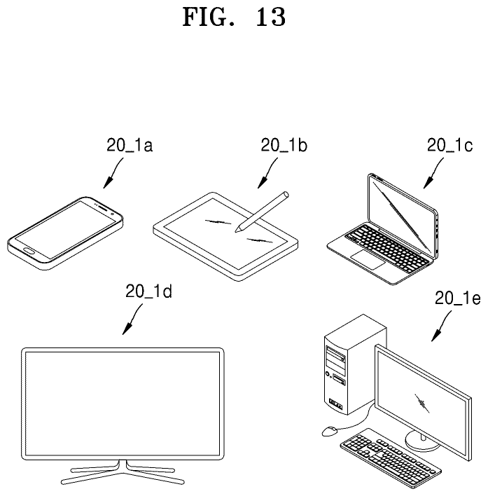

FIGS. 13 to 15 are schematic views of electronic devices according to various embodiments. FIGS. 13 to 15 illustrate examples of various electronic devices in which the display apparatus 1 according to embodiments is included.

FIG. 13 illustrates a smartphone 20_1a, a tablet PC 20_1b, a laptop computer 20_1c, a TV 20_1d, and a monitor 20_1e for a desktop, as examples of the electronic devices.

The smartphone 20_1a may include an input module, such as a touch sensor, etc., and a communication module, in addition to the display module 21. The smartphone 20_1a may process information received through the communication module or other input modules and display the processed information through a display module of the display apparatus 1.

The tablet PC 20_1b, the laptop computer 20_1c, the TV 20_1d, and the monitor 20_1c for a desk may also include a display module and an input module, similarly as the smartphone 20_1a, and may further include a communication module according to cases.

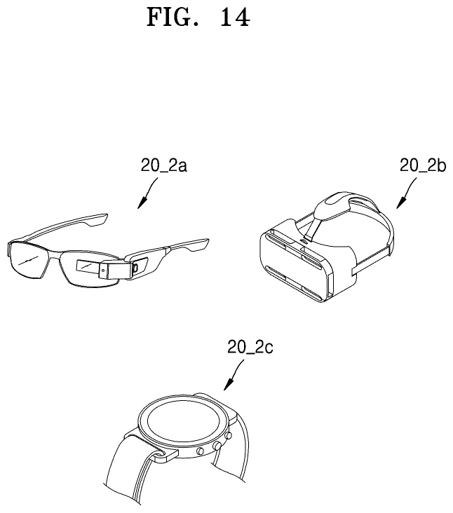

FIG. 14 illustrates cases where the electronic device 20 including the display module 21 includes a wearable electronic device. The wearable electronic device may include smart glasses 20_2a, an HMD 20_2b, a smart watch 20_2c, etc.

The smart glasses 20_2a and the HMD 20_2b may include a display module configured to project a display image and a reflector configured to reflect the projected display screen and provide the display screen to a user's eye, so as to provide a screen of virtual reality (VR) or augmented reality (AR) to the user.

The smart watch 20_2c may include a biometric sensor as an input device and may provide biometric information recognized through the biometric sensor to the user through a display module.

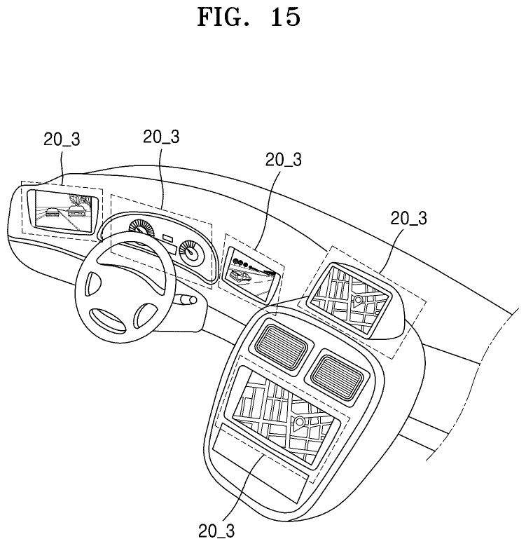

FIG. 15 illustrates a case where the electronic device 20 including the display module 21 includes a vehicle. For example, an electronic device 20_3 may be used in a gauge or a center fascia of the vehicle, a CID arranged on a dashboard of the vehicle, or a room mirror display substituting a side-view mirror.

Although not shown, the electronic device in which the display apparatus 1 according to embodiments is included, may include not only devices mainly including a screen display, such as an advertisement board, an electronic display board, a game machine, etc., but also various home appliances for displaying information through a display module, such as a refrigerator, a laundry machine, a dryer, an air conditioner, a robot cleaner, etc. Also, when the display module has a light-transmission function, the electronic device may include a smart window or a transparent display apparatus for displaying the background and a display image together. Types of the electronic devices according to embodiments are not limited to the examples described above, and various other electronic devices may also be provided.

As described above, according to the display apparatus according to the one or more of the above embodiments, interference between the display panel and the housing may be reduced.

As described above, according to the display apparatus according to the one or more of the above embodiments, an overlapping area of edges of the display panel may be reduced.

Embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims.

What is claimed is:

1. A display apparatus comprising:
a display panel comprising a first area that is foldable and flat and a second area that extends from the first area and is curved;
an optical functional layer on the first area and at least a portion of the second area, the optical functional layer having at least a portion which is curved;
a first cover member on the optical functional layer and overlapping the first area;
a second cover member on the first cover member, overlapping the first area and the second area, and having at least a portion which is curved; and
a housing in which the display panel, the optical functional layer, the first cover member, and the second cover member are accommodated.

2. The display apparatus of claim 1, further comprising a protective film on a lower surface of the display panel.

3. The display apparatus of claim 2, wherein the protective film comprises an opening area overlapping a boundary between the first area and the second area.

4. The display apparatus of claim 2, wherein the second area does not overlap a folding axis about which the display panel is foldable.

5. The display apparatus of claim 1, further comprising an elastic member between the housing and the display panel.

6. The display apparatus of claim 5, wherein the elastic member comprises a porous member or a member comprising an inner cavity.

7. The display apparatus of claim 5, wherein the housing comprises a mounting groove in which the elastic member is mounted.

8. The display apparatus of claim 1, wherein the first cover member overlaps only on the first area.

9. The display apparatus of claim 1, further comprising:
a cover member adhesive layer between the first cover member and the second cover member; and
a first adhesive member between the first cover member and the optical functional layer.

10. The display apparatus of claim 9, wherein at least a portion of the cover member adhesive layer and at least a portion of the first adhesive member are in contact with each other on the second area.

11. The display apparatus of claim 9, wherein at least a portion of the cover member adhesive layer and at least a portion of the first adhesive member are separated from each other on the second area.

12. The display apparatus of claim 1, further comprising a brush portion between the housing and the second cover member.

13. The display apparatus of claim 1, wherein a surface of the housing facing the second cover member is inclined or curved.

14. The display apparatus of claim 1, wherein a side surface of the housing comprises an avoidance groove.

15. A display apparatus comprising:
a display panel having a foldable portion;
a housing accommodating the display panel; and
an elastic member between the housing and the display panel and having a porous shape or comprising at least one cavity.

16. The display apparatus of claim 15, wherein the display panel comprises:
a first area that is flat; and
a second area that extends from the first area and is curved.

17. The display apparatus of claim 16, wherein the elastic member overlaps the second area.

18. The display apparatus of claim 16, further comprising a protective film comprising an opening area overlapping the first area and the second area and disposed below the display panel.

19. The display apparatus of claim 18, wherein the opening area does not overlap a folding axis about which the display panel is foldable.

20. The display apparatus of claim 18, wherein the opening area comprises a hole or a groove.

21. The display apparatus of claim 15, further comprising:
an optical functional layer on the display panel; and
a cover member on the optical functional layer.

22. The display apparatus of claim 21, wherein an end of an adhesive member on the cover member and an end of an adhesive member on the optical functional layer are in contact with each other, and at least a portion of the adhesive member on the cover member and at least a portion of the adhesive member on the optical functional layer are apart from each other.

23. The display apparatus of claim 1, further comprising a brush portion between the cover member and the housing.

24. The display apparatus of claim 15, wherein the housing comprises a mounting groove in which the elastic member is mounted.

25. The display apparatus of claim 15, wherein the housing comprises an avoidance groove accommodating a shifted end of the display panel when the display panel is folded.

26. An electronic device comprising:
a display panel comprising a first area that is foldable and flat and a second area that extends from the first area and is curved;
an optical functional layer on the first area and at least a portion of the second area, the optical functional layer having at least a portion which is curved;
a first cover member on the optical functional layer and overlapping the first area;
a second cover member on the first cover member, overlapping the first area and the second area, and having at least a portion which is curved; and
a housing in which the display panel, the optical functional layer, the first cover member, and the second cover member are accommodated.

27. The electronic device of claim 26, further comprising a protective film on a lower surface of the display panel and comprising an opening area that overlaps a boundary between the first area and the second area.

28. The electronic device of claim 26, further comprising an elastic member between the housing and the display panel.

29. The electronic device of claim 26, further comprising:
a cover member adhesive layer between the first cover member and the second cover member; and
a first adhesive member between the first cover member and the optical functional layer, at least a portion of the first adhesive member being in contact with the cover member adhesive layer in the first area.
